(19) United States
(12) Patent Application Publication
(10) Pub. No.: US 2025/0015151 A1
(43) Pub. Date: Jan. 9, 2025

(54) SEMICONDUCTOR DEVICE

(71) Applicant: ROHM CO., LTD., Kyoto-shi (JP)

(72) Inventor: Masaki NAGATA, Kyoto-shi (JP)

(73) Assignee: ROHM CO., LTD., Kyoto-shi (JP)

(21) Appl. No.: 18/890,814

(22) Filed: Sep. 20, 2024

Related U.S. Application Data
(63) Continuation of application No. PCT/JP2023/002429, filed on Jan. 26, 2023.

(30) Foreign Application Priority Data
Mar. 28, 2022 (JP) 2022-051509

(51) Int. Cl. H01L 29/417; H01L 29/06; H01L 29/40; H01L 29/423; H01L 29/66; H01L 29/78

(52) U.S. Cl. CPC H01L 29/41766; H01L 29/0692; H01L 29/402; H01L 29/41741; H01L 29/7813; H01L 29/0603; H01L 29/4236; H01L 29/66734

(57) ABSTRACT

A semiconductor device includes a semiconductor layer including a first surface and a second surface opposite to the first surface; a source trench formed in the semiconductor layer and including a side wall that is continuous with the second surface; an insulation layer formed on the second surface of the semiconductor layer; an embedded electrode arranged in the source trench and insulated from the side wall of the source trench by the insulation layer; a source interconnection formed on the insulation layer; and a source contact plug electrically connecting the source interconnection to the semiconductor layer. The source contact plug contacts the embedded electrode, and the source contact plug contacts the semiconductor layer via a part of the side wall of the source trench.

### CROSS-REFERENCE TO RELATED APPLICATIONS

The present application is a bypass continuation of International Patent Application No. PCT/JP2023/002429, filed on Jan. 26, 2023, which claims priority to Japanese Patent Application No. 2022-051509, filed on Mar. 28, 2022, the entire disclosures of these applications are incorporated herein by reference.

### BACKGROUND

### 1. Field

The present disclosure relates to a semiconductor device.

### 2. Description of Related Art

A known transistor has a trench gate structure in which a gate electrode is embedded in a gate trench. Japanese Laid-Open Patent Publication No. 2021-125649 discloses a semiconductor device including source contact holes, used to form source plug electrodes, and gate trenches that are arranged alternately.

### BRIEF DESCRIPTION OF THE DRAWINGS

FIG. 1 is a schematic plan view of an exemplary semiconductor device in accordance with a first embodiment.

FIG. 2 is a plan view showing terminal ends of gate trenches and source trenches.

FIG. 3 is a schematic cross-sectional view of the semiconductor device in accordance with the first embodiment taken along line F3-F3 in FIG. 2.

FIG. 4 is a schematic cross-sectional view of the semiconductor device in accordance with the first embodiment taken along line F4-F4 in FIG. 2.

FIG. 5 is a schematic cross-sectional view of the semiconductor device in accordance with the first embodiment taken along line F5-F5 in FIG. 2.

FIG. 6 is a schematic cross-sectional view illustrating an exemplary manufacturing step of the semiconductor device in accordance with the first embodiment.

FIG. 7 is a schematic cross-sectional view illustrating a manufacturing step following the step of FIG. 6.

FIG. 8 is a schematic cross-sectional view illustrating a manufacturing step following the step of FIG. 7.

FIG. 9 is a schematic cross-sectional view illustrating a manufacturing step following the step of FIG. 8.

FIG. 10 is a schematic cross-sectional view illustrating a manufacturing step following the step of FIG. 9.

FIG. 11 is a schematic cross-sectional view illustrating a manufacturing step following the step of FIG. 10.

FIG. 12 is a schematic cross-sectional view illustrating a manufacturing step following the step of FIG. 11.

FIG. 13 is a schematic cross-sectional view illustrating a manufacturing step following the step of FIG. 12.

FIG. 14 is a schematic cross-sectional view illustrating a comparative example of the semiconductor device.

FIG. 15 is a schematic cross-sectional view of an exemplary semiconductor device in accordance with a second embodiment.

FIG. 16 is a schematic cross-sectional view of the semiconductor device in accordance with the second embodiment taken along line F4-F4 in FIG. 2.

FIG. 17 is a schematic cross-sectional view illustrating an exemplary manufacturing step of the semiconductor device in accordance with the second embodiment.

FIG. 18 is a schematic cross-sectional view illustrating a manufacturing step following the step of FIG. 17.

FIG. 19 is a schematic cross-sectional view illustrating an exemplary semiconductor device in accordance with a first modified example.

FIG. 20 is a schematic cross-sectional view illustrating an exemplary semiconductor device in accordance with a second modified example.

### DETAILED DESCRIPTION

Several embodiments of a semiconductor device in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of exemplary methods, apparatuses, and/or systems in accordance with the present disclosure. This detailed description is illustrative and is not intended to limit embodiments of the present disclosure or the application and use of the embodiments.

### First Embodiment

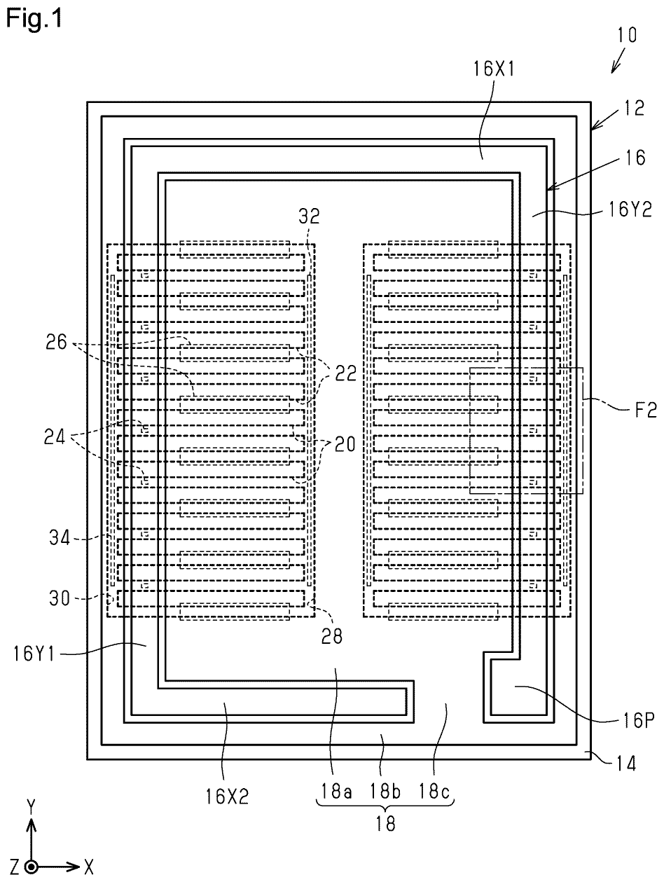

FIG. 1 is a schematic plan view of an exemplary semiconductor device 10 in accordance with a first embodiment. In this specification, the X-axis, Y-axis, and Z-axis are orthogonal to one another as shown in FIG. 1. The term “plan view” as used in this specification is a view of the semiconductor device 10 taken in the Z-axis direction. Unless otherwise indicated, the term “plan view” will refer to a view of the semiconductor device 10 taken from above along the Z-axis.

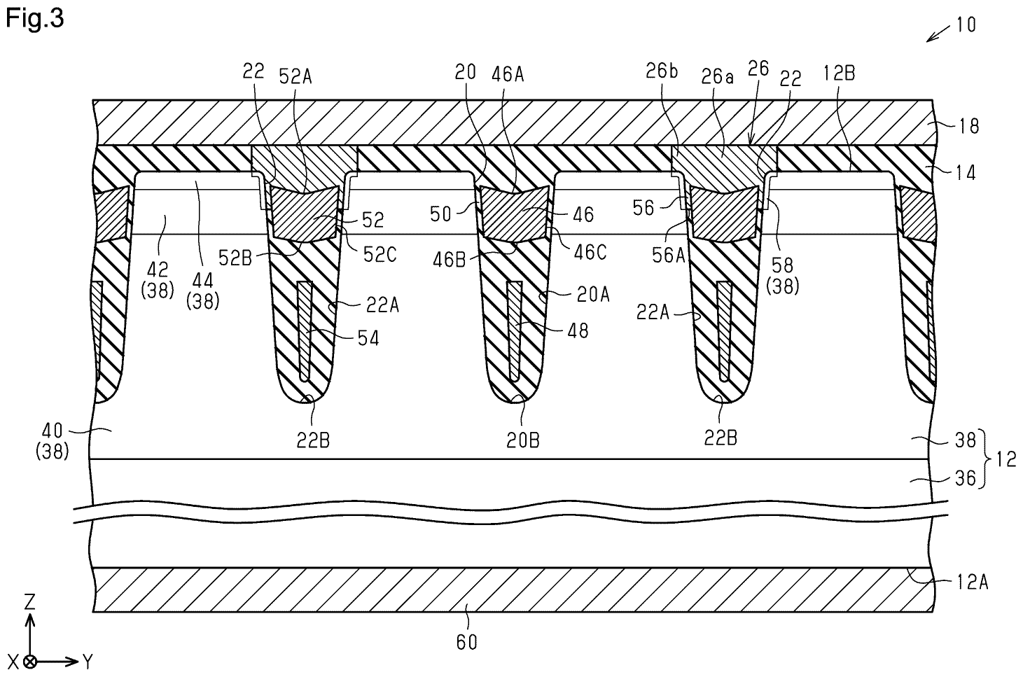

The semiconductor device 10 is, for example, a metal insulator semiconductor field effect transistor (MISFET) having, for example, a trench gate structure. The semiconductor device 10 includes a semiconductor layer 12 and an insulation layer 14 formed on the semiconductor layer 12. In one example, the semiconductor layer 12 may be formed from silicon (Si). As will be described later with reference to FIG. 3, the semiconductor layer 12 includes a first surface 12A and a second surface 12B opposite to the first surface 12A. In FIG. 1, the Z-axis direction may be orthogonal to the first surface 12A and the second surface 12B of the semiconductor layer 12. The semiconductor layer 12 is covered by the insulation layer 14. Thus, FIG. 1 shows only the rectangular contour of the semiconductor layer 12. In one example, the insulation layer 14 may be formed by a film of silicon oxide (SiO₂). In addition to or instead of the film of SiO₂, the insulation layer 14 may include a layer formed by a film of, for example, silicon nitride (SiN).

### Exemplary Planar Layout of Semiconductor Device

The semiconductor device 10 may further include a gate interconnection 16, which is formed on the insulation layer 14, and a source interconnection 18, which is formed on the insulation layer 14. The source interconnection 18 is insulated from the gate interconnection 16. The gate interconnection 16 and the source interconnection 18 may be formed from at least one of titanium (Ti), nickel (Ni), gold (Au), silver (Ag), copper (Cu), aluminum (Al), a copper alloy, and an aluminum alloy.

The gate interconnection 16 may generally extend along the outer edges of the semiconductor layer 12. In the example of FIG. 1, the gate interconnection 16 includes a first gate interconnection portion 16X1 and a second gate interconnection portion 16X2, which extend in the X-axis direction, and a third gate interconnection portion 16Y1 and a fourth gate interconnection portion 16Y2, which extend in the Y-axis direction. In the present specification, the X-axis direction will be referred to as the first direction, and the Y-axis direction will be referred to as the second direction. The first gate interconnection portion 16X1 is connected between one end of the third gate interconnection portion 16Y1 and one end of the fourth gate interconnection portion 16Y2. The second gate interconnection portion 16X2 is connected to the other end of the third gate interconnection portion 16Y1 but not to the other end of the fourth gate interconnection portion 16Y2. The gate interconnection 16 may further include a gate pad portion 16P. In the example of FIG. 1, the other end of the fourth gate interconnection portion 16Y2 is connected to the gate pad portion 16P. The first gate interconnection portion 16X1, the second gate interconnection portion 16X2, the third gate interconnection portion 16Y1, the fourth gate interconnection portion 16Y2, and the gate pad portion 16P may be formed integrally.

The source interconnection 18 may include an inner source interconnection portion 18a, which is at least partially surrounded by the gate interconnection 16, and an outer source interconnection portion 18b, which surrounds the gate interconnection 16. The source interconnection 18 may further include a source connecting portion 18c connecting the part between the inner source interconnection portion 18a and the outer source interconnection portion 18b. In the example of FIG. 1, the gate interconnection 16 has the form of an open loop partially surrounding the inner source interconnection portion 18a. The source connecting portion 18c, which is located at the part where the loop of the gate interconnection 16 opens, connects the inner source interconnection portion 18a to the outer source interconnection portion 18b. The inner source interconnection portion 18a, the outer source interconnection portion 18b, and the source connecting portion 18c may be formed integrally. In the example of FIG. 1, the source connecting portion 18c extends between the second gate interconnection portion 16X2 and the gate pad portion 16P. In another example, the loop of the gate interconnection 16 may be open at a different location. In a further example, the gate interconnection 16 may have the form of a closed loop in plan view.

The semiconductor device 10 may further include a gate trench 20 formed in the semiconductor layer 12. In the present specification, the gate trench 20 refers to a trench that receives a gate electrode 46, which will be described later with reference to FIG. 3. The gate trench 20 may be arranged to overlap both the gate interconnection 16 and the source interconnection 18 at least partially in plan view. The semiconductor device 10 may include multiple gate trenches 20, and some of the gate trenches 20 may be arranged at equal intervals parallel to one another. In the example of FIG. 1, each gate trench 20 extends in the X-axis direction and intersects the third gate interconnection portion 16Y1 or the fourth gate interconnection portion 16Y2 in plan view.

The semiconductor device 10 further includes a source trench 22 formed in the semiconductor layer 12. In the present embodiment, the source trench 22 refers to a trench that receives an embedded electrode 52, which will be described with reference to FIG. 3. The source trench 22 may be arranged to overlap both the gate interconnection 16 and the source interconnection 18 at least partially in plan view. The semiconductor device 10 may include multiple source trenches 22, and some of the source trenches 22 may be arranged at equal intervals parallel to one another. In the example of FIG. 1, each source trench 22 extends in the X-axis direction and intersects the third gate interconnection portion 16Y1 or the fourth gate interconnection portion 16Y2 in plan view.

The source trenches 22 may extend parallel to the gate trenches 20 in plan view. When the gate trenches 20 and the source trenches 22 extend in the X-axis direction (first direction), the gate trenches 20 and the source trenches 22 may be arranged alternately in the Y-axis direction (second direction, which is orthogonal to first direction) in plan view.

In the example of FIG. 1, the gate trenches 20 each have a width (dimension in Y-axis direction) that is the same as that of each of the source trenches 22. In another example, the width of the gate trenches 20 may differ from the width of the source trenches 22. For example, the source trenches 22 may have a greater width than the gate trenches 20.

The semiconductor device 10 may further include gate contact plugs 24 and source contact plugs 26. The gate contact plugs 24 are connected to the gate interconnection 16. The gate contact plugs 24 may be arranged in a region where the gate trenches 20 intersect the gate interconnection 16 in plan view. The source contact plugs 26 are connected to the source interconnection 18. The source contact plugs 26 are arranged to overlap the inner source interconnection portion 18a in plan view. The source contact plugs 26 may extend parallel to the source trenches 22 in plan view. In the example of FIG. 1, the source contact plugs 26 extend in the X-axis direction in plan view. The source contact plugs 26 may at least partially overlap the source trenches 22 in plan view. The source contact plugs 26 may be arranged so as not to overlap the gate trenches 20 in plan view.

The semiconductor device 10 may include first terminal trenches 28 and second terminal trenches 30 that are formed in the semiconductor layer 12. In the example of FIG. 1, the first terminal trenches 28 overlap the inner source interconnection portion 18a in plan view. Further, the second terminal trenches 30 overlap the outer source interconnection portion 18b in plan view. The gate trenches 20 and the source trenches 22 extend between and are in communication with the first terminal trenches 28 and the second terminal trenches 30.

The semiconductor device 10 may further include first field plate contact plugs 32 and second field plate contact plugs 34. The first field plate contact plugs 32 and the second field plate contact plugs 34 extend in the Y-axis direction in the example of FIG. 1. The first field plate contact plugs 32 may overlap the first terminal trenches 28 in plan view and be connected to the inner source interconnection portion 18a. The second field plate contact plugs 34 may overlap the second terminal trenches 30 in plan view and be connected to the outer source interconnection portion 18b.

The gate contact plugs 24, the source contact plugs 26, the first field plate contact plugs 32, and the second field plate contact plugs 34 may each be formed from any metal material. In one example, the contact plugs 24, 26, 32, and 34 may each be formed from at least one of tungsten (W), titanium (Ti), and titanium nitride (TiN).

The planar layout of the semiconductor device 10 is not limited to the example of FIG. 1. For example, the semiconductor device 10 does not have to include the terminal trenches 28 and 30. In this case, the field plate conductor plugs 32 and 34 may be arranged to overlap the ends of the gate trenches 20 and the source trenches 22. For example, the semiconductor device 10 does not have to include the source interconnection 18. In this case, the field plate conductor plugs 30 may be arranged to overlap the ends of the gate trenches 20. In addition to or instead of the gate trenches 20 and the source trenches 22, for example, the semiconductor device 10 may further include gate trenches 20 and source trenches 22 that extend in the Y-axis direction. In this case, the first gate interconnection portion 16X1 and the second gate interconnection portion 16X2 may intersect the gate trenches 20 and the source trenches 22 that extend in the Y-axis direction.

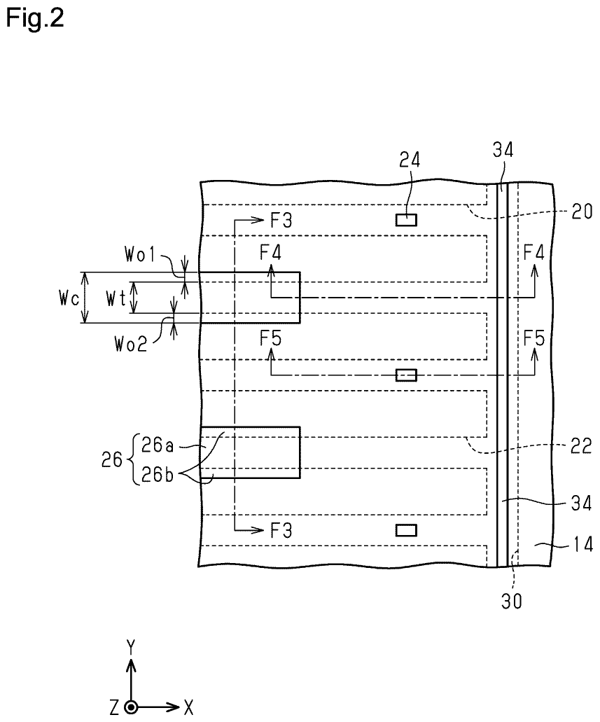

FIG. 2 is a plan view showing the terminal ends of the gate trenches 20 and the source trenches 22. FIG. 2 is an enlarged view of region F2 illustrated in FIG. 1 and shows the gate trenches 20 and the source trenches 22 that are in communication with the second terminal trench 30. The gate interconnection 16 and the source interconnection 18 are not shown in FIG. 2. The contact plugs 24, 26, and 34 formed on the insulation layer 14 are shown in solid lines, and the trenches 20, 22, and 30 formed in the semiconductor layer 12 under the insulation layer 14 are shown in broken lines.

The gate contact plugs 24 may each have a smaller width (dimension in Y-axis direction in illustrated example) than the gate trenches 20. Thus, the gate contact plugs 24 are arranged in the gate trenches 20 in plan view.

The source contact plugs 26 may each have a larger width (dimension in Y-axis direction in illustrated example) than the source trenches 22. Thus, when Wc represents the width of each source contact plug 26 and Wt represents the width of each source trench 22, Wc>Wt is satisfied.

Each source contact plug 26 may at least partially overlap the corresponding source trench 22 in plan view. As shown in FIG. 2, each source contact plug 26 includes a portion arranged in the corresponding source trench 22 and a portion arranged outside the source trench 22 in plan view. In the present specification, the part of the source contact plug 26 arranged in the source trench 22 in plan view will be referred to as the main portion 26a. The width of the main portion 26a is Wt and is the same as the width of the source trench 22. Further, in the present specification, the part of the source contact plug 26 arranged outside the source trench in plan view with be referred to as the overhanging portion 26b. As shown in FIG. 3, when the two overhanging portions 26b at opposite sides of the main portion 26a have widths respectively represented by Wo1 and Wo2, Wo1+Wo2=Wc−Wt is satisfied. The value of Wc−Wt may be determined taking into consideration a margin allowed for positioning the source contact plug 26 with respect to the source trench 22. In one example, the width of the source contact plug 26 may be determined so that even when the source contact plug 26 is maximally displaced with respect to the source trench 22, the two overhanging portions 26b will still exist (Wo1,Wo2>0). The width of each of the elements described above may be, for example, a width in a plane including the second surface 12B of the semiconductor layer 12.

FIG. 3 is a schematic cross-sectional view of the semiconductor device in accordance with the first embodiment taken along line F3-F3 in FIG. 2. In FIG. 3, the gate trenches 20 and the source trenches 22 are arranged alternately in the Y-axis direction.

The semiconductor layer 12 may include a semiconductor substrate 36 and an epitaxial layer 38 formed on the semiconductor substrate 36. In this case, the semiconductor substrate 36 includes the first surface 12A of the semiconductor layer 12, and the epitaxial layer 38 includes the second surface 12B of the semiconductor layer 12. In one example, the semiconductor substrate 36 may be a Si substrate. The semiconductor substrate 36 corresponds to a drain region of the MISFET. The epitaxial layer 38 may be a Si layer that is epitaxially grown on the Si substrate. The epitaxial layer 38 may include a drift region 40, a body region 42 formed on the drift region 40, and a source region 44 formed on the body region 42. The source region 44 may include the second surface 12B of the semiconductor layer 12.

The drain region (semiconductor substrate 36) may be an n-type region containing n-type impurities. The drain region (semiconductor substrate 36) may have an n-type impurity concentration in a range from 1×10¹⁸ cm⁻³ to 1×10²⁰ cm⁻³, inclusive. The drain region (semiconductor substrate 36) may have a thickness in a range from 50 μm to 450 μm, inclusive.

The drift region 40 may be an n-type region containing n-type impurities at a lower concentration than the drain region (semiconductor substrate 36). The drift region 40 may have an n-type impurity concentration in a range from 1×10¹⁵ cm⁻³ to 1×10¹⁸ cm⁻³. The drift region 40 may have a thickness in a range from 1 μm to 25 μm, inclusive.

The body region 42 may be a p-type region containing p-type impurities. The body region 42 may have a p-type impurity concentration in a range from 1×10¹⁶ cm⁻³ to 1×10¹⁸ cm⁻³, inclusive. The body region 42 may have a thickness in a range from 0.2 μm to 1.0 μm, inclusive.

The source region 44 may be an n-type region containing n-type impurities at a higher concentration than the drift region 40. The source region 44 may have an n-type impurity concentration in a range from 1×10¹⁹ cm⁻³ to 1×10²¹ cm⁻³, inclusive. The source region 44 may have a thickness in a range from 0.1 μm to 1 μm, inclusive.

In the present disclosure, p-type is also referred to as a first conductivity type, and n-type is referred to as a second conductivity type. The n-type impurities may be, for example, phosphorus (P), arsenic (As), or the like. The p-type impurities may be, for example, boron (B), aluminum (Al), or the like.

### Details of Gate Trench

Each gate trench 20 includes an opening in the second surface 12B of the semiconductor layer 12 and has a depth in the Z-axis direction. In the present specification, the Z-axis direction is also referred to as the depth direction. The gate trench 20 extends through the source region 44 and the body region 42 of the semiconductor layer 12 to the drift region 40. The gate trench 20 includes a side wall 20A and a bottom wall 20B. The bottom wall 20B is adjacent to the drift region 40. The gate trench 20 may have a depth in a range from 1 μm to 10 μm, inclusive.

The side wall 20A of the gate trench 20 may extend in a direction orthogonal to the second surface 12B of the semiconductor layer 12 (Z-axis direction) or be inclined relative to the Z-axis direction. In one example, the side wall 20A may be inclined relative to the Z-axis direction so that the width of the gate trench 20 decreases toward the bottom wall 20B. Further, the bottom wall 20B of the gate trench 20 does not necessarily have to be flat and may be, for example, partially or entirely curved.

The semiconductor device 10 may further include the gate electrode 46 and a field plate electrode 48 that are arranged in each gate trench 20. The gate electrode 46 is electrically connected to the gate interconnection 16. The gate electrode 46 is electrically connected by the corresponding gate contact plug 24 (refer to FIG. 1) to the gate interconnection 16. The field plate electrode 48 is electrically connected to the source interconnection 18. The field plate electrode 48 may be electrically connected by the first and second field plate conductor plugs 32 and 34 (refer to FIG. 1) to the source interconnection 18. The gate electrode 46 and the field plate electrode 48 are formed from polysilicon, which is conductive.

The gate electrode 46 includes an upper surface 46A, which is covered by the insulation layer 14, and a bottom surface 46B opposite to the upper surface 46A. The field plate electrode 48 may be arranged in the gate trench 20 below the gate electrode 46. In further detail, the field plate electrode 48 may be arranged between the bottom surface 46B of the gate electrode 46 and the bottom wall 20B of the gate trench 20. At least part of the bottom surface 46B of the gate electrode 46 may face the field plate electrode 48 with the insulation layer 14 located in between. The gate electrode 46 further includes a side surface 46C facing the side wall 20A of the gate trench 20.

The upper surface 46A of the gate electrode 46 may be located below the second surface 12B of the semiconductor layer 12. Further, the bottom surface 46B of the gate electrode 46 is located relatively close to the interface of the drift region 40 and the body region 42 in the Z-axis direction, preferably downward from the interface. The upper surface 46A and the bottom surface 46B of the gate electrode 46 may be flat or curved.

The gate electrode 46 and the field plate electrode 48 are surrounded by the insulation layer 14. The field plate electrode 48 may have a smaller width than the gate electrode 46. When the field plate electrode 48 has a relatively small width, the insulation layer 14 surrounding the field plate electrode 48 has a relatively large width. This mitigates electric field concentration in the gate trench 20.

The insulation layer 14 includes a gate insulation portion 50 that is located between the gate electrode 46 and the semiconductor layer 12 and covers the side wall 20A of the gate trench 20. The gate insulation portion 50 is a part of the insulation layer 14 that is located between the side surface 46C of the gate electrode 46 and the side wall 20A of the gate trench 20. The gate insulation portion 50 is in contact with both the side surface 46C of the gate electrode 46 and the side wall 20A of the gate trench 20. When predetermined voltage is applied to the gate electrode 46, a channel forms in the p-type body region 42, which is adjacent to the gate insulation portion 50. The semiconductor device 10 allows for control of the flow of electrons through the channel between the n-type source region 44 and the n-type drift region 40 in the Z-axis direction.

### Details of Source Trench

Each source trench 22 includes an opening in the second surface 12B of the semiconductor layer 12 and has a depth in the Z-axis direction. The source trench 22 extends through the source region 44 and the body region 42 of the semiconductor layer 12 to the drift region 40. The source trench 22 includes a side wall 22A and a bottom wall 22B. The bottom wall 20B is adjacent to the drift region 40. The source trench 22 may have a depth in a range of 1 μm to 10 μm, inclusive.

The side wall 22A of the source trench 22 may extend in a direction orthogonal to the second surface 12B of the semiconductor layer 12 (Z-axis direction) or be inclined relative to the Z-axis direction. In one example, the side wall 22A may be inclined relative to the Z-axis direction so that the width of the source trench 22 decreases toward the bottom wall 22B. Further, the bottom wall 22B of the source trench 22 does not necessarily have to be flat and may be, for example, partially or entirely curved.

The source trench 22 may be similar in shape to the gate trench 20. For example, the source trench 22 may have the same width and depth as the gate trench 20. In another example, the source trench 22 may differ in shape from the gate trench 20. For example, the source trench 22 may have a greater width and/or depth than the gate trench 20.

The semiconductor device 10 may further include the embedded electrode 52 and a field plate electrode 54 arranged in each source trench 22. The embedded electrode 52 may be electrically connected to the source interconnection 18 by the corresponding source contact plug 26. The field plate electrode 54 may be electrically connected by the corresponding first and second field plate conductor plugs 32 and 34 (refer to FIG. 1) to the source interconnection 18. To distinguish the field plate electrode 48 arranged in the gate trench 20 from the field plate electrode 54 arranged in the source trench 22, the field plate electrode 48 and the field plate electrode 54 may be respectively referred to as the first field plate electrode 48 and the second field plate electrode 54. The embedded electrode 52 and the field plate electrode 54 may be formed from polysilicon, which is conductive.

The embedded electrode 52 includes an upper surface 52A, which is covered by the source contact plug 26, and a bottom surface 52B opposite to the upper surface 52A. The field plate electrode 54 may be arranged in the source trench 22 below the embedded electrode 52. In further detail, the field plate electrode 54 may be arranged between the bottom surface 52B of the embedded electrode 52 and the bottom wall 22B of the source trench 22. At least part of the bottom surface 52B of the embedded electrode 52 may face the field plate electrode 54 with the insulation layer 14 located in between. The embedded electrode 52 further includes a side surface 52C facing the side wall 22A of the source trench 22.

The upper surface 52A of the embedded electrode 52 may be located downward from the second surface 12B of the semiconductor layer 12. Further, the bottom surface 52B of the embedded electrode 52 is located relatively close to the interface of the drift region 40 and the body region 42 in the Z-axis direction, preferably, downward from the interface. The upper surface 52A and the bottom surface 52B of the embedded electrode 52 may be flat or curved.

When the source trench 22 is similar in shape to the gate trench 20, the embedded electrode 52 and the field plate electrode 54 may respectively be similar in shape to the gate electrode 46 and the field plate electrode 48. The field plate electrode 54 may have a smaller width than the embedded electrode 52.

The field plate electrode 54 is surrounded by the insulation layer 14. In addition to the insulation layer 14, the embedded electrode 52 may be surrounded by the corresponding source contact plug 26. The upper surface 52A of the embedded electrode 52 is adjacent to the source contact plug 26. The bottom surface 52B of the embedded electrode 52 is adjacent to the insulation layer 14. Part of the side surface 52C of the embedded electrode 52 is adjacent to the source contact plug 26, and the remaining part of the side surface 52C is adjacent to the insulation layer 14.

### Details of Source Contact Plug and Contact Region

The source contact plugs 26 electrically connect the source interconnection 18 to the semiconductor layer 12. Each source contact plug 26 contacts the corresponding embedded electrode 52 and contacts the semiconductor layer 12 via the side wall 22A of the source trench 22.

The source contact plug 26 includes a lower extension 56 embedded between the side wall 22A of the source trench 22 and the side surface 52C of the embedded electrode 52. The lower extension 56 includes a lower end surface 56A located between the upper surface 52A and the bottom surface 52B of the embedded electrode 52 in the Z-axis direction. Thus, part of the side surface 52C of the embedded electrode 52 is adjacent to the lower extension 56, and the remaining part of the side surface 52C is adjacent to the insulation layer 14. In one example, the lower end surface 56A of the lower extension 56 may be located closer to the bottom surface 52B of the embedded electrode 52 than to the upper surface 52A in the Z-axis direction. The lower end surface 56A of the lower extension 56 may be located upward from the boundary of the body region 42 and the drift region 40 in the Z-axis direction.

As described with reference to FIG. 2, each source contact plug 26 includes the main portion 26a arranged in the corresponding source trench 22 in plan view and the overhanging portions 26b arranged outside the source trench in plan view. The lower extension 56 is included in the main portion 26a. As shown in FIG. 3, the overhanging portions 26b are in contact with the second surface 12B of the semiconductor layer 12. Each overhanging portion 26b may be a part of the source contact plug 26 that extends between the second surface 12B of the semiconductor layer 12 and the source interconnection 18. The overhanging portion 26b extends on a part of the second surface 12B that is continuous with the side wall 22A of the source trench 22. The overhanging portion 26b may have a width (dimension in Y-axis direction in FIG. 3) that is determined in accordance with the alignment precision of the source trenches 22 and the source contact plugs 26 in a manufacturing process.

The semiconductor layer 12 may further include contact regions 58 formed adjacent to each source contact plug 26. Each contact region 58 extends along part of the side wall 22A of the source trench 22 in the semiconductor layer 12. As shown in FIG. 3, the side wall 22A of the source trench 22 generally extends in the Z-axis direction. Thus, the contact region 58 also generally extends in the Z-axis direction.

The contact region 58 may further extend along part of the second surface 12B that is continuous with the side wall 22A of the source trench 22 in the semiconductor layer 12. That is, the contact region 58 may be a region in the semiconductor layer 12 that includes surfaces contacting the source contact plug 26 and the semiconductor layer 12. The contact region 58 is electrically connected by the source contact plug 26 to the source interconnection 18 formed on the insulation layer 14.

The contact regions 58 may be p-type regions containing P-type impurities. The contact regions 58 have a higher impurity concentration than the body region 42. The contact regions 58 may have a p-type impurity concentration in a range from 1×10¹⁹ cm⁻³ to 1×10²¹ cm⁻³, inclusive.

The semiconductor device 10 may further include a drain electrode 60 formed on the first surface 12A of the semiconductor layer 12. The drain electrode 60 is located adjacent to and electrically connected to the drain region (semiconductor substrate 36). The drain electrode 60 may be formed from at least one of titanium (Ti), nickel (Ni), gold (Au), silver (Ag), copper (Cu), aluminum (Al), a copper alloy, and an aluminum alloy.

### Details of Electrode at Terminal End of Trench

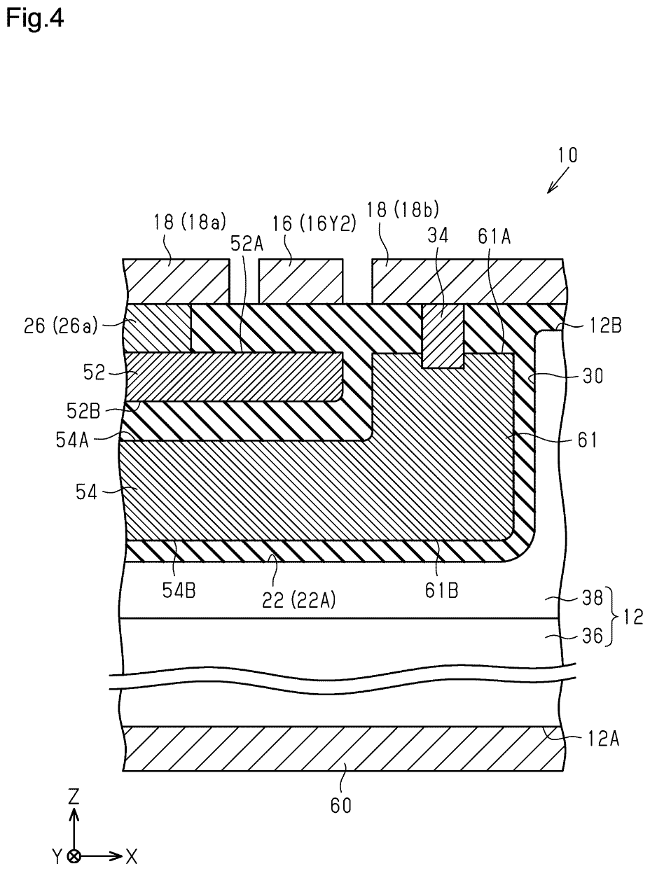

FIG. 4 is a schematic cross-sectional view of the semiconductor device 10 in accordance with the first embodiment taken along line F4-F4 in FIG. 2. FIG. 4 shows the cross section taken at an end of a source trench 22. The end of the source trench 22 is in communication with the corresponding second terminal trench 30. The semiconductor device 10 may further include a terminal electrode 61 arranged in each second terminal trench 30 and extending in the Y-axis direction. The terminal electrode 61 may be connected to the second field plate electrode 54. The terminal electrode 61 may be formed integrally with the second field plate electrode 54. The terminal electrode 61 includes an upper surface 61A located relatively close to the second surface 12B of the semiconductor layer 12 in the Z-axis direction. This allows the corresponding second field plate contact plug 34 to electrically connect the source interconnection 18 (outer source interconnection portion 18b) to the terminal electrode 61. The second field plate contact plug 34 may extend through the upper surface 61A of the terminal electrode 61 and be partially embedded in the terminal electrode 61. Although the upper surface 61A of the terminal electrode 61 is located upward from an upper surface 54A of the second field plate electrode 54, a bottom surface 61B of the terminal electrode 61 may be located at substantially the same position as a bottom surface 54B of the second field plate electrode 54 in the Z-axis direction.

The source contact plug 26 is in contact with the upper surface 52A of the embedded electrode 52. The lower extension 56 of the source contact plug 26 is not shown in FIG. 4. The embedded electrode 52 does not extend to the second terminal trench 30 in the X-axis direction. The embedded electrode 52 is insulated by the insulation layer 14 from the second field plate electrode 54 and the terminal electrode 61. The embedded electrode 52 is, however, electrically connected to the inner source interconnection portion 18a, and the terminal electrode 61 is electrically connected to the outer source interconnection portion 18b. Thus, the embedded electrode 52, the second field plate electrode 54, and the terminal electrode 61 may each be electrically connected to the source interconnection 18.

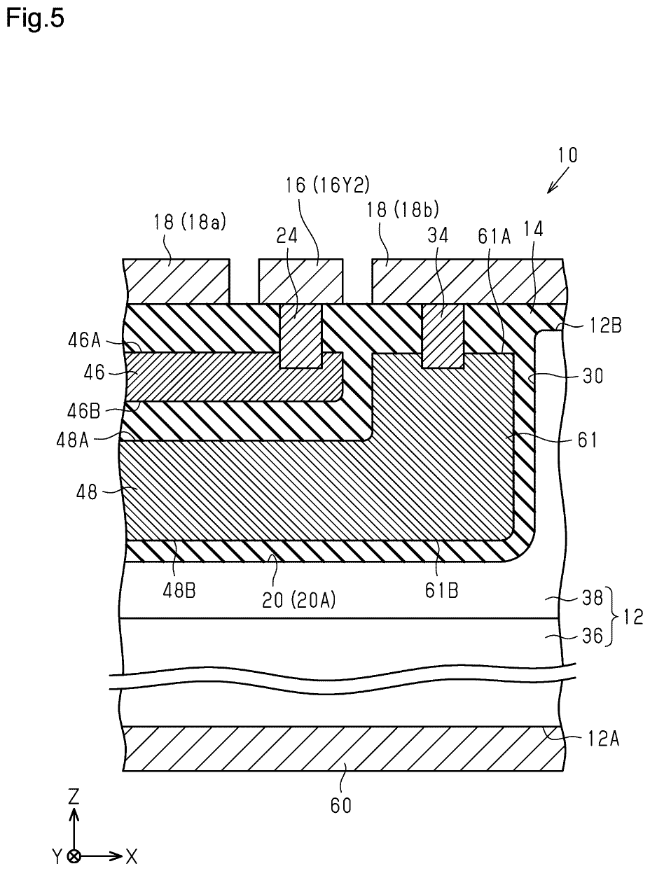

FIG. 5 is a schematic cross-sectional view of the semiconductor device 10 in accordance with the first embodiment taken along line F5-F5 in FIG. 2. FIG. 5 shows the cross section taken at an end of a gate trench 20. The end of the gate trench 20 is in communication with the corresponding second terminal trench 30. The terminal electrode 61 may be connected to the first field plate electrode 48. The terminal electrode 61 may be formed integrally with the first field plate electrode 48 in addition to the second field plate electrode 54. Thus, the first field plate electrode 48 and the second field plate electrode 54 are electrically connected to each other by the terminal electrode 61. Although the upper surface 61A of the terminal electrode 61 is located upward from an upper surface 48A of the first field plate electrode 48, the bottom surface 61B of the terminal electrode 61 may be located at substantially the same position as a bottom surface 48B of the first field plate electrode 48 in the Z-axis direction.

The gate contact plug 24 electrically connects the gate interconnection 16 (fourth gate interconnection portion 16Y2) to the gate electrode 46. The gate contact plug 24 may extend through the upper surface 46A of the gate electrode 46 and be partially embedded in the gate electrode 46. The gate electrode 46 does not extend to the second terminal trench 30 in the X-axis direction. The gate electrode 46 is insulated by the insulation layer 14 from the first field plate electrode 48 and the terminal electrode 61.

### Method for Manufacturing Semiconductor Device

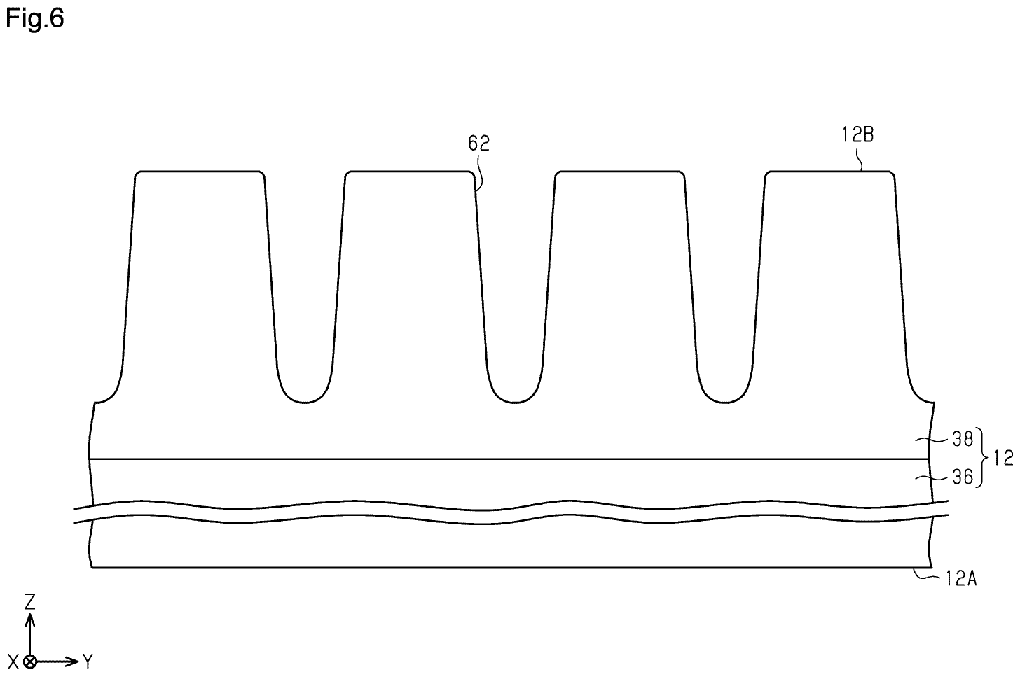

One example of a method for manufacturing the semiconductor device 10 in accordance with the first embodiment will now be described. FIGS. 6 to 13 are schematic cross-sectional views illustrating exemplary manufacturing steps of the semiconductor device 10. To aid understanding, in FIGS. 6 to 13, same reference characters are given to those elements that are the same as the corresponding elements shown in FIG. 3.

As shown in FIG. 6, the method for manufacturing the semiconductor device 10 includes forming the semiconductor layer 12, and forming trenches 62 in the semiconductor layer 12. The formation of the semiconductor layer 12 may include forming the epitaxial layer 38 on the semiconductor substrate 36. The semiconductor substrate 36 may be a Si substrate containing n-type impurities. The epitaxial layer 38 may be an n-type Si layer that is doped with n-type impurities and epitaxially grown on the semiconductor substrate 36. In this step, etching is performed with a mask (not shown) having a predetermined pattern and formed on the epitaxial layer 38 to selectively remove parts of the epitaxial layer 38. This forms the trenches 62 having openings in the second surface 12B of the semiconductor layer 12.

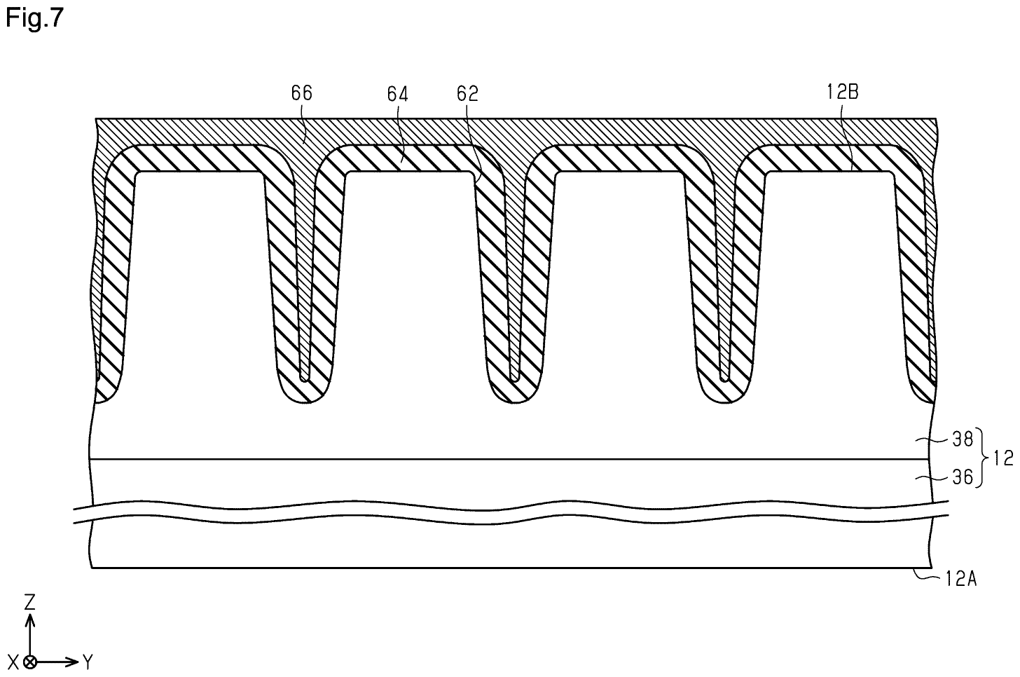

FIG. 7 is a schematic cross-sectional view illustrating a manufacturing step following the step of FIG. 6. As shown in FIG. 7, the method includes forming a first insulation layer 64 on the semiconductor layer 12, and forming a first conductive layer 66 on the first insulation layer 64. The first insulation layer 64 is formed along the second surface 12B of the semiconductor layer 12 and the trenches 62. In one example, the first insulation layer 64 is formed from SiO₂ through thermal oxidation. In another example, the first insulation layer 64 may be formed from SiO₂ through chemical vapor deposition (CVD). Then, the first conductive layer 66 is formed on the first insulation layer 64. This fills the trenches 62 with the first insulation layer 64 and the first conductive layer 66. The first conductive layer 66 may be formed from, for example, polysilicon, which is conductive.

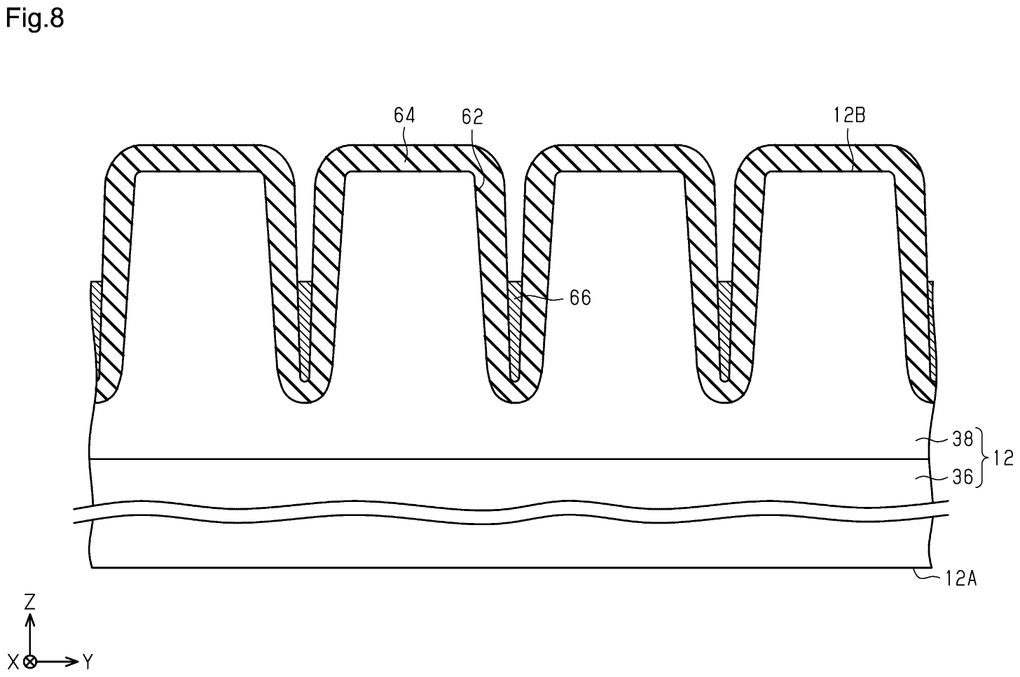

FIG. 8 is a schematic cross-sectional view illustrating a manufacturing step following the step of FIG. 7. As shown in FIG. 8, the method includes etching and removing parts of the first conductive layer 66. In this step, etching of the first conductive layer 66 exposes the first insulation layer 64, which covers the second surface 12B of the semiconductor layer 12, and results in the surface of the first conductive layer 66 being located downward from the second surface 12B of the semiconductor layer 12 (at an intermediate position in trenches 62) in the Z-axis direction.

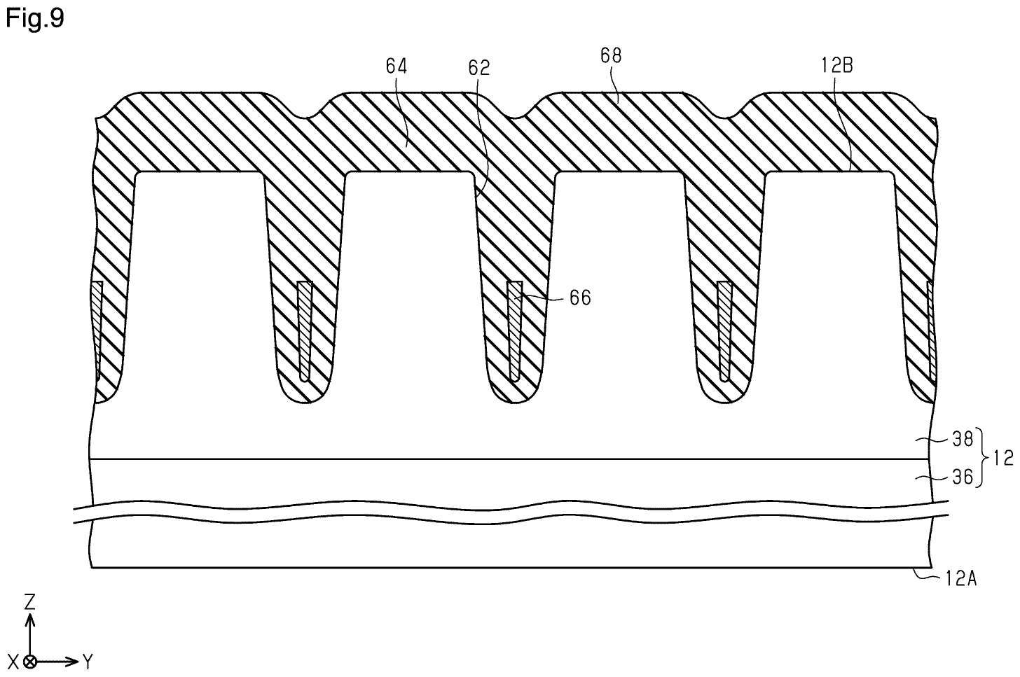

FIG. 9 is a schematic cross-sectional view illustrating a manufacturing step following the step of FIG. 8. As shown in FIG. 9, the method includes forming a second insulation layer 68 on the first insulation layer 64 and the first conductive layer 66. This covers the surface of the first conductive layer 66 in the trenches 62 with the second insulation layer 68. The second insulation layer 68 is formed from SiO₂ in the same manner as the first insulation layer 64. The second insulation layer 68 may be formed from SiO₂ through thermal oxidation, CVD, or a combination of thermal oxidation and CVD. As a result, the trenches 62 are filled with the first conductive layer 66, the first insulation layer 64, and the second insulation layer 68.

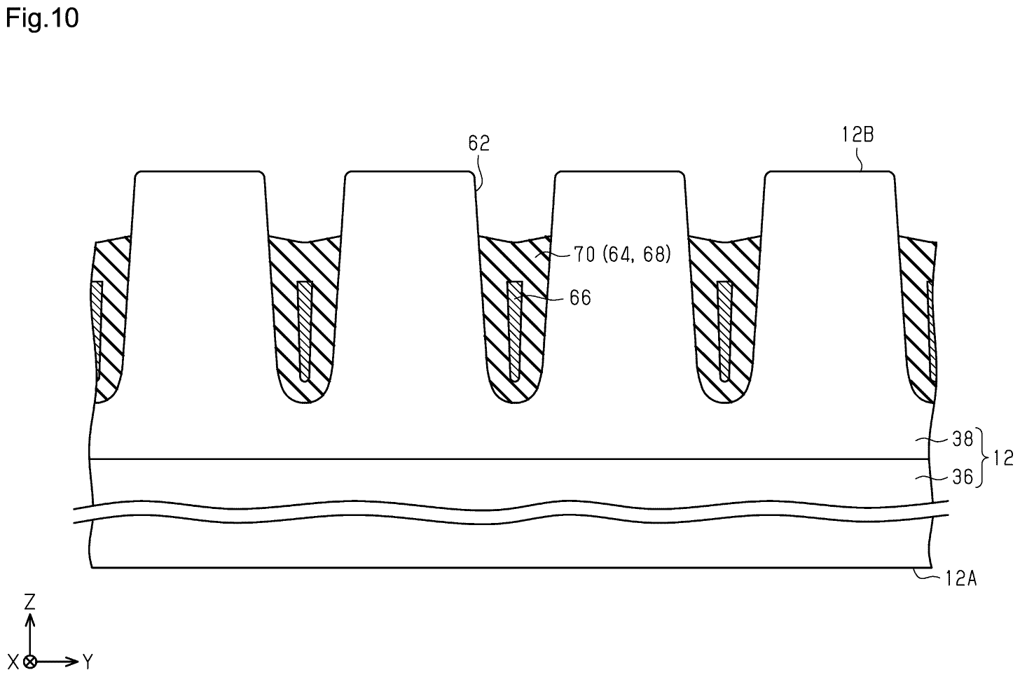

FIG. 10 is a schematic cross-sectional view illustrating a manufacturing step following the step of FIG. 9. As shown in FIG. 10, the method includes partially removing the first insulation layer 64 and the second insulation layer 68 to expose parts of the trenches 62 and expose the second surface 12B of the semiconductor layer 12. The removal of the first insulation layer 64 and the second insulation layer 68 is performed through, for example, chemical mechanical polishing, dry etching, and/or wet etching. In the description hereafter, the residue of the first insulation layer 64 and the second insulation layer 68 in the trenches 62 is collectively referred to as the third insulation layer 70. The surface of the third insulation layer 70 in the trenches 62 may be located upward from the first conductive layer 66 in the Z-axis direction. Thus, the first conductive layer 66 is surrounded by the third insulation layer 70.

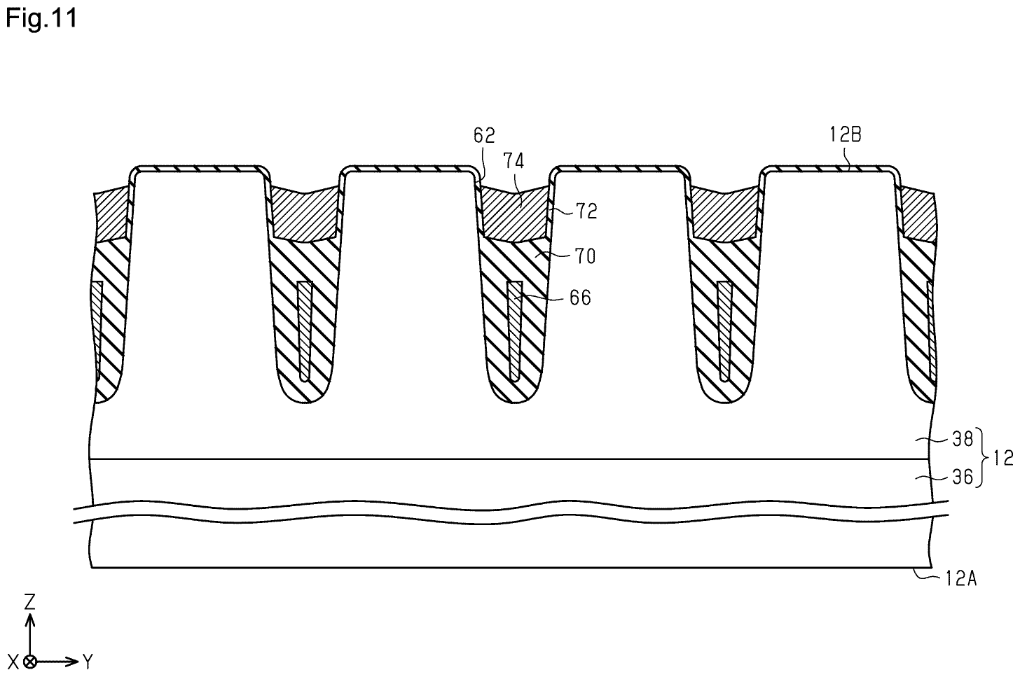

FIG. 11 is a schematic cross-sectional view illustrating a manufacturing step following the step of FIG. 10. The method includes forming a fourth insulation layer 72, and forming a second conductive layer 74 on the fourth insulation layer 72. In one example, the fourth insulation layer 72 may be formed from SiO₂ through thermal oxidation. In one example, the fourth insulation layer 72 may be formed from SiO₂ through CVD. The fourth insulation layer 72 is relatively thin and formed along the second surface 12B of the semiconductor layer 12, the surface of the third insulation layer 70, and the parts of the trenches 62 exposed in the step illustrated in FIG. 10. After forming a film of a conductive material on the fourth insulation layer 72 so as to fill the trenches 62, the conductive material is etched to a given depth to form the second conductive layer 74. This exposes the fourth insulation layer 72 that covers the second surface 12B of the semiconductor layer 12. Further, the surface of the second conductive layer 74 becomes located downward from the second surface 12B of the semiconductor layer 12 in the Z-axis direction. The second conductive layer 74 may be formed from, for example, polysilicon, which is conductive.

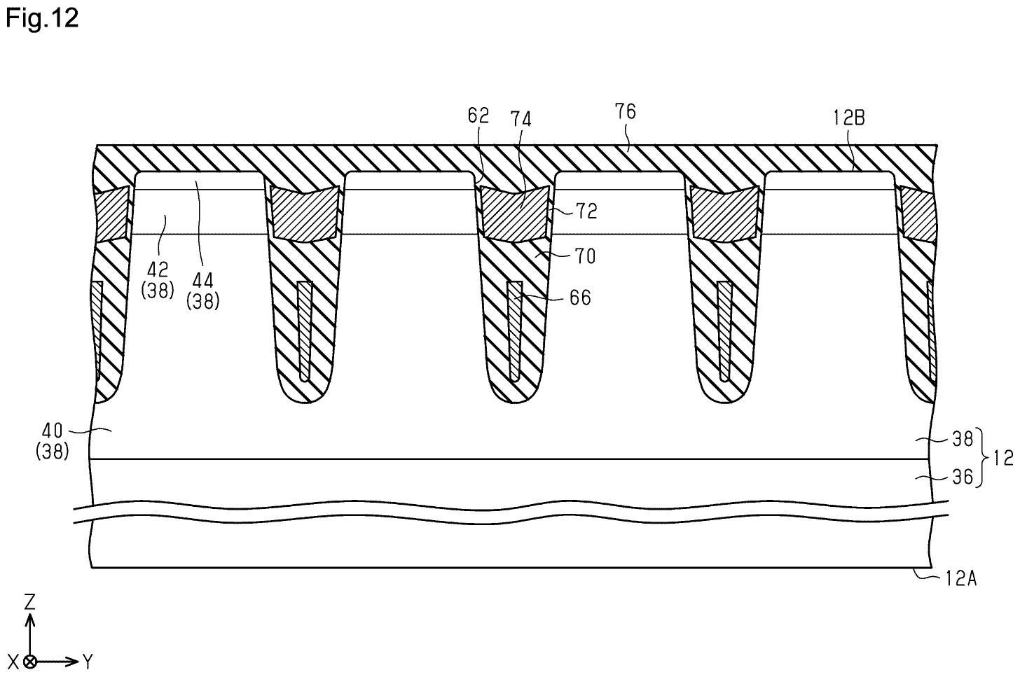

FIG. 12 is a schematic cross-sectional view illustrating a manufacturing step following the step of FIG. 11. As shown in FIG. 12, the method includes forming the drift region 40, the body region 42, and the source region 44 in the epitaxial layer 38, and forming a fifth insulation layer 76 on the fourth insulation layer 72 and the second conductive layer 74. In this step, ion implantation is performed to implant p-type impurities and then n-type impurities from the surface of the epitaxial layer 38 (second surface 12B of the semiconductor layer 12), which is an n-type Si layer. In one example, the fifth insulation layer 76 is formed through CVD from SiO₂, SiN, or a combination of these compositions.

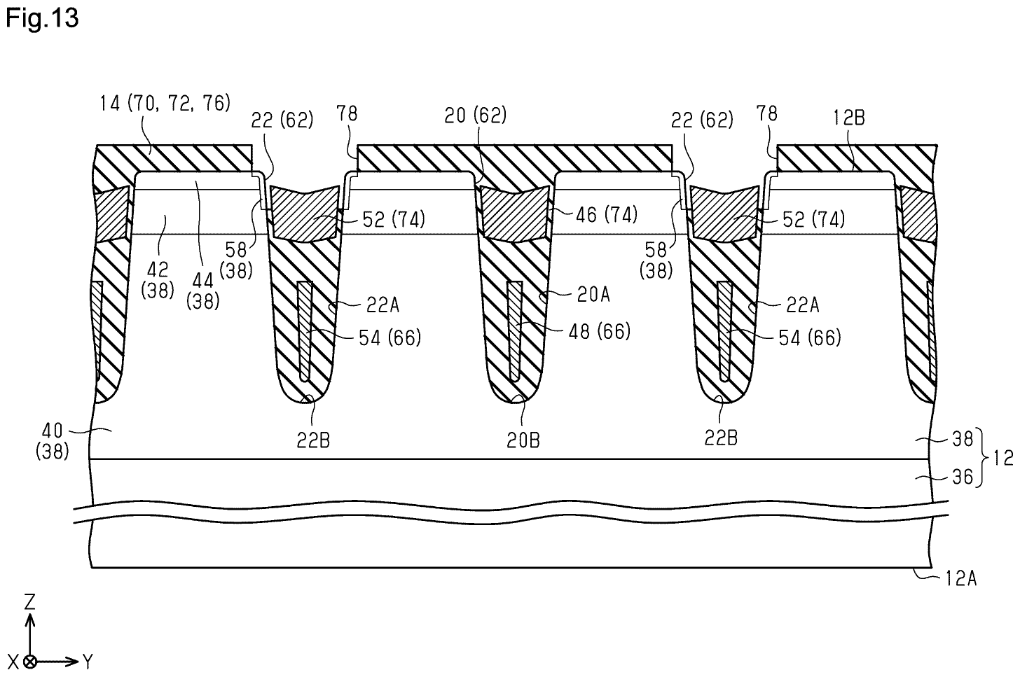

FIG. 13 is a schematic cross-sectional view illustrating a manufacturing step following the step of FIG. 12. As shown in FIG. 13, the method includes forming source contact openings 78 in the insulation layer 14, and forming the contact regions 58. The insulation layer 14 includes the third insulation layer 70, the fourth insulation layer 72, and the fifth insulation layer 76 that are shown in FIG. 12. The source contact openings 78 may be formed by selectively removing the insulation layer 14 from above certain ones of the trenches 62. In one example, a source contact opening 78 is formed above every other one of the trenches 62. The trenches 62 where the source contact openings 78 are formed correspond to the source trenches 22 shown in FIG. 3, and the trenches 62 where the source contact openings 78 are not formed correspond to the gate trenches 20 shown in FIG. 3. Accordingly, the second conductive layer 74 in the trenches 62 (source trenches 22) where the source contact openings 78 are formed correspond to the embedded electrodes 52 shown in FIG. 3.

The formation of the source contact openings 78 includes partially exposing the side wall 22A of each source trench 22. The source contact openings 78 are formed so that the exposed parts of the side walls 22A partially face the second conductive layer 74 corresponding to the embedded electrodes 52. The source contact openings 78 do not have to be formed at a position deeper than the boundary of the body region 42 and the drift region 40 in the Z-axis direction. Further, the source contact openings 78 have a greater width in the Y-axis direction than the trenches 62. Thus, the formation of the source contact openings 78 includes exposing parts of the second surface 12B of the semiconductor layer 12 that are continuous with the side walls 22A.

The contact region 58 may be formed by implanting ions from the exposed parts of the side walls 22A of the source trenches 22. In further detail, p-type impurities are implanted from the exposed parts of the side walls 22A of the source trenches 22 and from the exposed parts of the second surface 12B of the semiconductor layer 12 to form the contact region 58 that has a higher p-type impurity concentration than the body region 42. The contact regions 58 may be formed along the exposed parts of the second surface 12B of the semiconductor layer 12 and the exposed parts of the side walls 22A of the source trenches 22.

After the step of FIG. 13, the source contact openings 78 are filled with metal (e.g., W, Ti, TiN, or any combination of these substances) to form the source contact plugs 26 shown in FIG. 3. The gate interconnection 16 and the source interconnection 18 are formed on the insulation layer 14 (refer to FIG. 1). Then, the drain electrode 60 is formed on the first surface 12A of the semiconductor layer 12 (refer to FIG. 2) to obtain the semiconductor device 10 shown in FIG. 3.

The method for manufacturing the semiconductor device 10 has been described including a number of manufacturing steps that are sequentially performed. However, it should be acknowledged that several manufacturing steps may be performed in parallel and/or in a different order. Further, several manufacturing steps may be omitted, and steps differing from the above example may be performed.

### Operation

The operation of the semiconductor device 10 in accordance with the present embodiment will now be described.

The semiconductor device 10 includes the source contact plugs 26 that electrically connect the source interconnection 18 to the semiconductor layer 12. Each source contact plug 26 contacts the embedded electrode 52 embedded in the corresponding source trench 22 and contacts the semiconductor layer 12 via a part of the side wall 22A of the source trench 22. Thus, the position where the source contact plug 26 contacts the semiconductor layer 12 is aligned with the side wall 22A of the source trench 22. This reduces variations in the characteristics of the semiconductor device 10 (e.g., gate threshold voltage, on resistance, etc.) that would be caused by displacement of the source contact plugs 26.

As shown in FIG. 3, the side wall 22A of the source trench 22 generally extends in the Z-axis direction. Thus, the surface of the source contact plug 26 contacting the semiconductor layer 12 also extends in the Z-axis direction. This allows the area of contact between the source contact plug 26 and the semiconductor layer 12 to be maintained even when the source contact plug 26 is displaced in the Y-axis direction.

For instance, in the example shown in FIG. 2, when the source contact plug 26 is displaced relative to the source trench 22 in the Y-axis direction, the widths of the two overhanging portions 26b will become unequal (Wo1 Wo2). Even in this case, the source contact plug 26 will be arranged overlapping the side wall 22A of the source trench 22 in plan view. This allows the position where the source contact plug 26 contacts the semiconductor layer 12 to be aligned with the side wall 22A of the source trench 22.

### Comparative Example

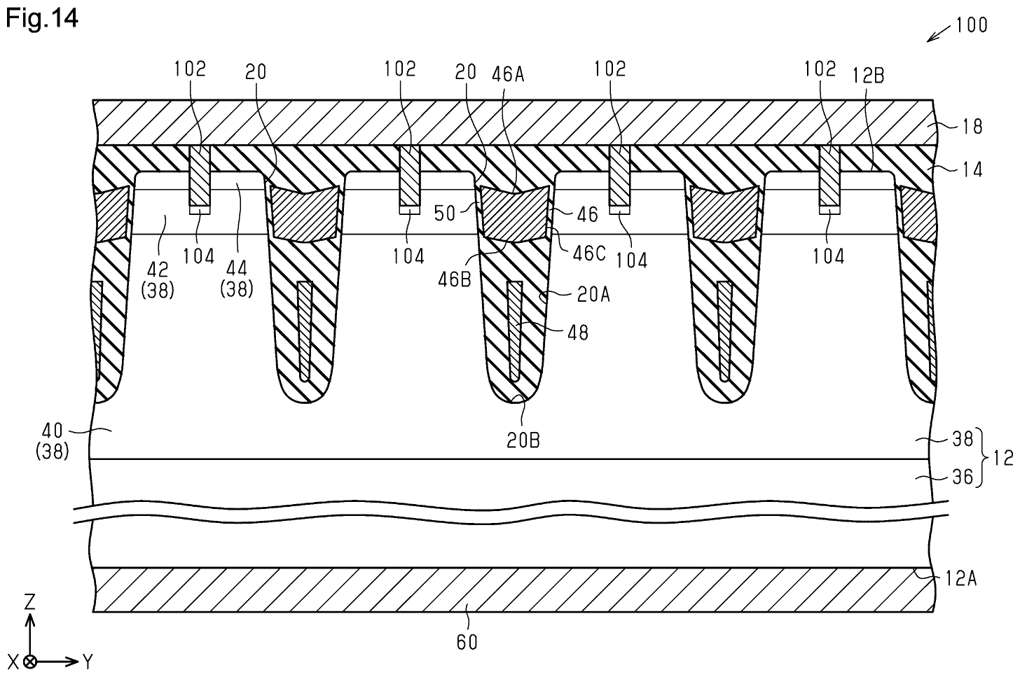

FIG. 14 is a schematic cross-sectional view showing a semiconductor device 100 of a comparative example. In FIG. 14, the same reference characters are given to those elements that are the same as the corresponding elements of the semiconductor device 10. Elements that are the same as the corresponding components of the semiconductor device 10 will not be described in detail.

The semiconductor device 100 does not include the source trenches 22 and the source contact plugs 26 shown in FIG. 3. In FIG. 3, the semiconductor layer 12 includes the gate trenches 20. The semiconductor device 100 includes source contact plugs 102 electrically connecting the source interconnection 18 to the semiconductor layer 12. Each source contact plug 102 extends parallel to the gate trenches 20 and is arranged between two of the gate trenches 20.

The semiconductor layer 12 includes contact regions 104. The contact regions 104 are p-type regions containing p-type impurities in the same manner as the contact regions 58 shown in FIG. 3. Each source contact plug 102 extends through the insulation layer 14 and the source region 44 to the body region 42 and contacts a corresponding one of the contact regions 104. Thus, the source contact plugs 102 electrically connect the source interconnection 18, which is formed on the insulation layer 14, to the contact regions 104 of the semiconductor layer 12.

In the semiconductor device 100, the position where each source contact plug 102 contacts the semiconductor layer 12 is directly dependent on where the source contact plug 102 is located. Thus, the characteristics of the semiconductor device 100 are apt to being affected by displacement of the source contact plugs 102.

In contrast, with the semiconductor device 10 of the present embodiment, even if the source contact plugs 26 were to be displaced, the position where each source contact plug 26 contacts the semiconductor layer 12 is aligned with the side wall 22A of the corresponding source trench 22. This reduces variations in characteristics that would be caused by displacement of the source contact plugs 26 of the semiconductor device 10.

Further, in the semiconductor device 100, the source contact plugs 102 are each located between two of the gate trenches 20. Thus, when considering the dimensions and displacement of the source contact plugs 102, it will be difficult to narrow the interval between the gate trenches 20. In contrast, with the semiconductor device 10 of the present embodiment, the source contact plugs 26 are not arranged between the trenches 20 and 22. This allows the interval between the trenches 20 and 22 to be narrowed in a relatively simple manner.

### Advantages

The semiconductor device 10 of the present embodiment has the advantages described below.

(1) The semiconductor device 10 includes the source contact plugs 26 that electrically connect the source interconnection 18 to the semiconductor layer 12. Each source contact plug 26 contacts the embedded electrode 52 embedded in the corresponding source trench 22 and contacts the semiconductor layer 12 via a part of the side wall 22A of the source trench 22. Thus, the position where the source contact plug 26 contacts the semiconductor layer 12 is aligned with the side wall 22A of the source trench 22. This reduces variations in the characteristics of the semiconductor device 10 that would be caused by displacement of the source contact plugs 26.

(2) The source contact plug 26 may include the lower extension 56 embedded between the side wall 22A of the source trench 22 and the side surface 52C of the embedded electrode 52. This allows the source contact plug 26 to be extended to a relatively deep position. Thus, current generated by inductive load when the semiconductor device 10 is turned off can be released from the source contact plug 26 effectively. Consequently, the inductive load resistance of the semiconductor device 10 may be improved.

(3) The lower extension 56 includes the lower end surface 56A, which is located between the upper surface 52A and the bottom surface 52B of the embedded electrode 52, and the lower end surface 56A is located closer to the bottom surface 52B of the embedded electrode 52 than to the upper surface 52A in the depth direction. This allows the source contact plug 26 to be extended to a deeper position and further improves the inductive load resistance of the semiconductor device 10.

(4) The source contact plug 26 may include the overhanging portions 26b that contact the second surface 12B of the semiconductor layer 12. This provides a margin for alignment of the source contact plug 26 with respect to the source trench 22 and ensures that the source contact plug 26 contacts the semiconductor layer 12.

(5) The semiconductor layer 12 includes the contact regions 58 of the first conductivity type formed adjacent to the source contact plugs 26, and each contact region 58 extends along part of the side wall 22A of the corresponding source trench 22. This improves the electric connection of the source contact plug 26 and the semiconductor layer 12.

(6) The contact region 58 may further extend along part of the second surface 12B of the semiconductor layer 12. This increases the area of contact between the source contact plugs 26 and the contact region 58 of the semiconductor layer 12, and further improves the electric connection of the source contact plugs 26 and the semiconductor layer 12.

(7) The semiconductor device 10 may include the field plate electrode 48 located below the gate electrode 46 in each gate trench 20. This allows the breakdown voltage to be maintained even when the impurity concentration of the epitaxial layer 38 is increased to decrease the on resistance of the semiconductor device 10. Further, the gate-drain capacitance can be decreased. This allows the switching speed of the semiconductor device 10 to be increased.

(8) The contact regions 58 are formed by implanting ions from the exposed parts of the side walls 22A of the source trenches 22. This allows each contact region 58 to extend along part of the side wall 22A of the corresponding source trench 22.

### Second Embodiment

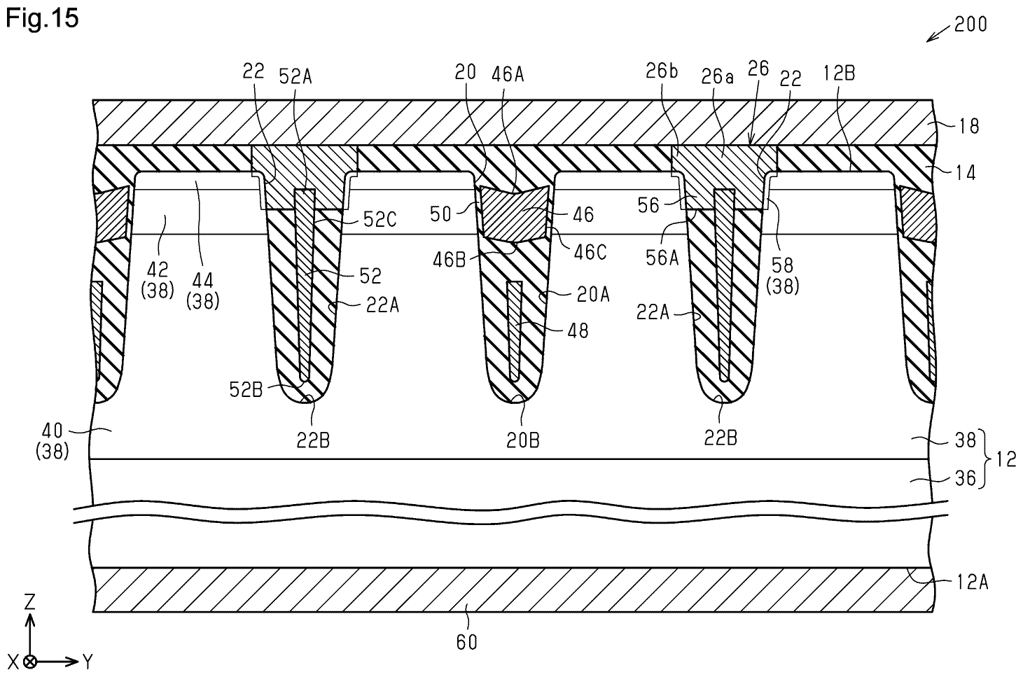

FIG. 15 is a schematic cross-sectional view of an exemplary semiconductor device 200 in accordance with a second embodiment. In FIG. 15, the same reference characters are given to those elements that are the same as the corresponding elements of the semiconductor device 10. Elements that are the same as the corresponding components of the semiconductor device 10 will not be described in detail.

In the semiconductor device 200 shown in FIG. 15, although the embedded electrode 52 is arranged in each source trench 22, the second field plate electrode 54 shown in FIG. 3 is not arranged therein. Thus, in the second embodiment, the bottom surface 52B of the embedded electrode 52 is located closer to the bottom wall 22B of the source trench 22 than in the first embodiment.

In the first embodiment shown in FIG. 3, the bottom surface 52B of the embedded electrode 52 is located closer to the interface of the drift region 40 and the body region 42 in the Z-axis direction than to the bottom wall 22B of the source trench 22. In the second embodiment, the bottom surface 52B of the embedded electrode 52 is located closer to the bottom wall 22B of the source trench 22 in the Z-axis direction than to the interface of the drift region 40 and the body region 42. The arrangement of the gate electrode 46 and the first field plate electrode 48 in each gate trench 20 is the same as that in the semiconductor device 10 of the first embodiment.

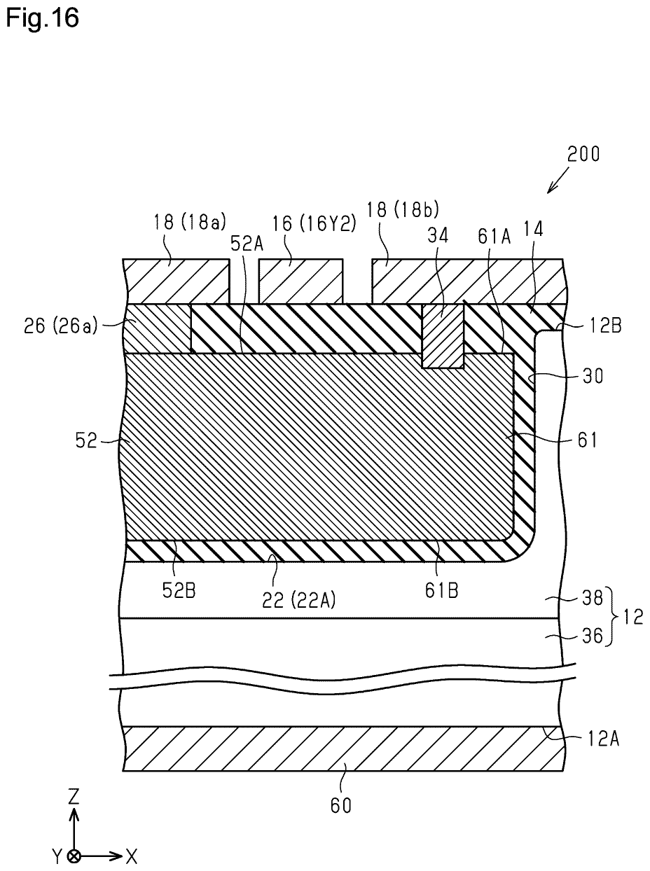

FIG. 16 is a schematic cross-sectional view of the semiconductor device 200 in accordance with the second embodiment taken along line F4-F4 in FIG. 2. FIG. 16 shows a cross section taken at an end of a source trench 22. In the semiconductor device 10 shown in FIG. 4, the terminal electrode 61 is connected to the second field plate electrode 54. In the semiconductor device 200, the terminal electrode 61 may be connected to the embedded electrode 52. In the second embodiment, the terminal electrode 61 is formed integrally with the embedded electrode 52. The upper surface 61A and the bottom surface 61B of the terminal electrode 61 may be located at substantially the same position as the upper surface 52A and the bottom surface 52B of the embedded electrode 52 in the Z-axis direction. The embedded electrode 52 and the terminal electrode 61, which are formed integrally, may extend below the gate interconnection 16 and be connected to the inner source interconnection portion 18a and the outer source interconnection portion 18b of the source interconnection 18.

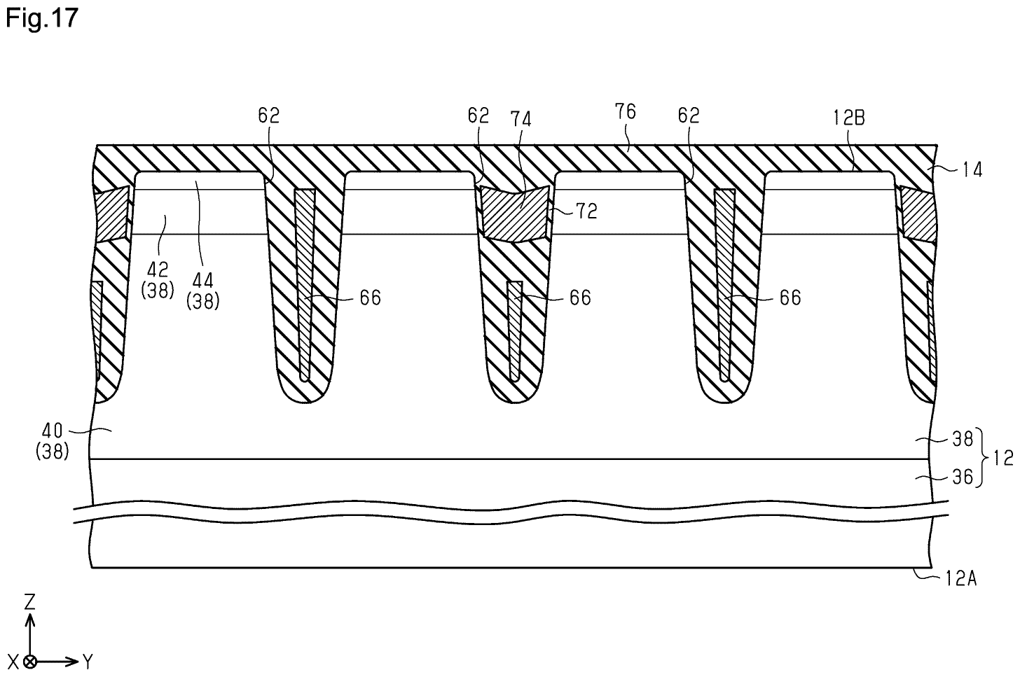

One example of a method for manufacturing the semiconductor device 200 in accordance with the second embodiment will now be described. In the same manner as the manufacturing method of the first embodiment, the semiconductor device 200 includes the steps illustrated in FIGS. 6 and 7. The semiconductor device 200 of the second embodiment may be manufactured by forming only one electrode from the first conductive layer 66 in every other one of the trenches 62 in the steps from the step illustrated in FIG. 8 of the first embodiment. In the step of FIG. 17, the trenches 62 in which two electrodes are formed from the first conductive layer 66 and the second conductive layer 74 and the trenches 62 in which one electrode is formed from the first conductive layer 66 are alternately arranged.

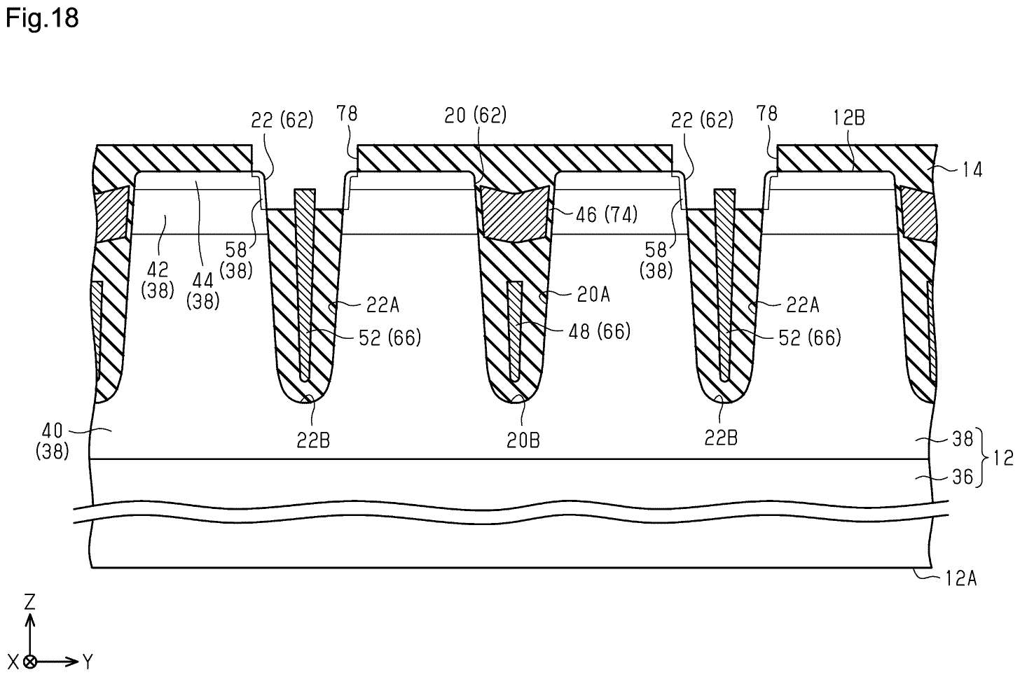

FIG. 18 is a schematic cross-sectional view illustrating a manufacturing step following the step of FIG. 17. As shown in FIG. 18, the method includes forming the source contact openings 78 in the insulation layer 14, and forming the contact regions 58. The source contact openings 78 may be formed by selectively removing the insulation layer 14 from above the ones of the trenches 62 in which one electrode is formed from the first conductive layer 66. In one example, a source contact opening 78 is formed above every other one of the trenches 62. The trenches 62 where the source contact openings 78 are formed correspond to the source trenches 22 shown in FIG. 15, and the trenches 62 where the source contact openings 78 are not formed correspond to the gate trenches 20 shown in FIG. 15. Thus, the first conductive layer 66 in the trenches 62 (source trenches 22) where the source contact openings 78 are formed correspond to the embedded electrodes 52 shown in FIG. 15.

The formation of the source contact openings 78 includes partially exposing the side wall 22A of each source trench 22. The source contact openings 78 are formed so that the exposed parts of the side walls 22A partially face the first conductive layer 66 corresponding to the embedded electrodes 52. In the example shown in FIG. 18, the source contact openings 78 are not formed as deep as the boundary between the body region 42 and the drift region 40 in the Z-axis direction. Further, the source contact openings 78 have a greater width in the Y-axis direction than the trenches 62. Thus, the formation of the source contact openings 78 include exposing parts of the second surface 12B of the semiconductor layer 12 that are continuous with the side walls 22A.

The contact regions 58 are formed by implanting ions from the exposed second surface 12B of the semiconductor layer 12 and each side wall 22A. In further detail, p-type impurities are implanted from the exposed second surface 12B of the semiconductor layer 12 and the side walls 22A to form the contact regions 58 that have a higher p-type impurity concentration than the body region 42. The contact regions 58 may be formed along the exposed second surface 12B of the semiconductor layer 12 and the side walls 22A.

After the step of FIG. 18, the source contact openings 78 are filled with metal (e.g., W, Ti, TiN, or any combination of these substances) to form the source contact plugs 26 shown in FIG. 15. The gate interconnection 16 and the source interconnection 18 are formed on the insulation layer 14 (refer to FIG. 1). Then, the drain electrode 60 (refer to FIG. 2) is formed on the first surface 12A of the semiconductor layer 12 to obtain the semiconductor device 200 shown in FIG. 15.

The semiconductor device 200 includes the source contact plugs 26 that electrically connect the source interconnection 18 to the semiconductor layer 12. Each source contact plug 26 contacts the embedded electrode 52 embedded in the corresponding source trench 22 and contacts the semiconductor layer 12 via a part of the side wall 22A of the source trench 22. Thus, the position where the source contact plug 26 contacts the semiconductor layer 12 is aligned with the side wall 22A of the source trench 22. This reduces variations in the characteristics of the semiconductor device 200 (e.g., gate threshold voltage, on resistance, etc.) that would be caused by displacement of the source contact plugs 26. The semiconductor device 200 of the second embodiment has advantages (1) to (8) of the semiconductor device 10 of the first embodiment.

### MODIFIED EXAMPLES

The above-described embodiments and modified examples may be modified as described below.

### First Modified Example

In the semiconductor device 200 of the second embodiment, the lower end surface 56A of the lower extension 56 of each source contact plug 26 may be located at a different position in the Z-axis direction.

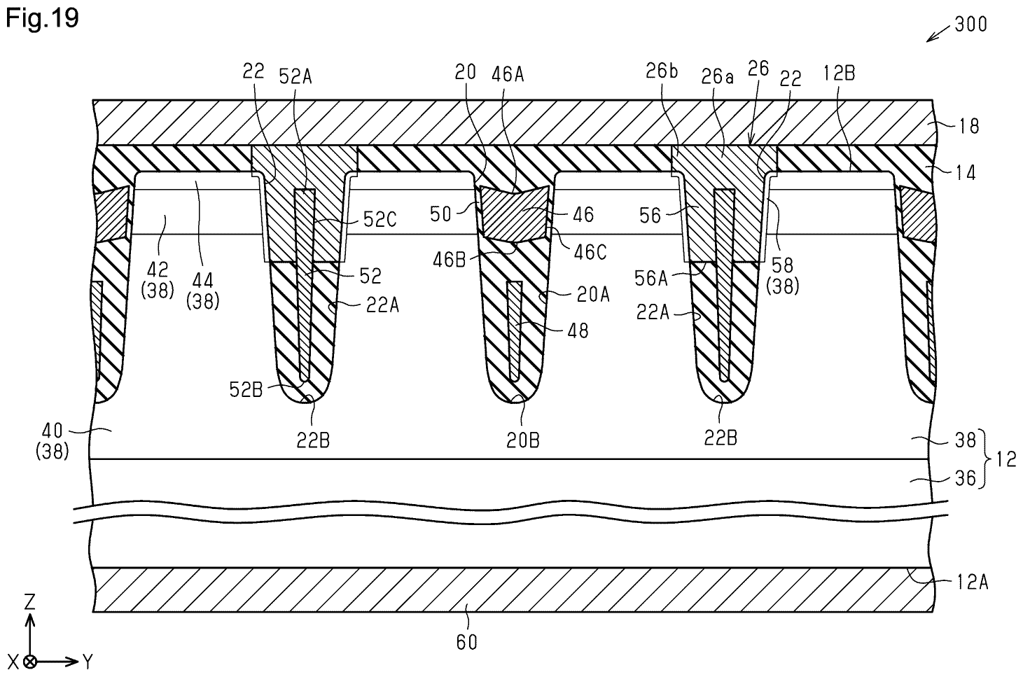

FIG. 19 is a schematic cross-sectional view illustrating a semiconductor device 300 in accordance with a first modified example. In FIG. 19, the same reference characters are given to those elements that are the same as the corresponding elements of the semiconductor device 200. Elements that are the same as the corresponding components of the semiconductor device 200 will not be described in detail.

The lower end surface 56A of the lower extension 56 of the semiconductor device 300 shown in FIG. 19 may be located downward from the boundary of the body region 42 and the drift region 40 in the Z-axis direction. In further detail, the lower end surface 56A may be located between the bottom surface 52B of the embedded electrode 52 and the boundary of the body region 42 and the drift region 40 in the Z-axis direction.

With the semiconductor device 300 of the first modified example, the source contact plugs 26 can be extended further downward in the Z-axis direction than the semiconductor device 200. This further improves the inductive load resistance of the semiconductor device 300. In addition, the depletion layer in the semiconductor layer 12 can be extended easily. This reduces the on-resistance of the semiconductor device 300 and increases the breakdown voltage.

### Second Modified Example

In the example of FIG. 3, the upper surface 52A of each embedded electrode 52 is completely covered by the corresponding source contact plug 26, and the source contact plug 26 has a greater width than the corresponding source trench 22. The semiconductor device 400 of the second modified example may include source contact plugs 402 that differ from those in the example of FIG. 3.

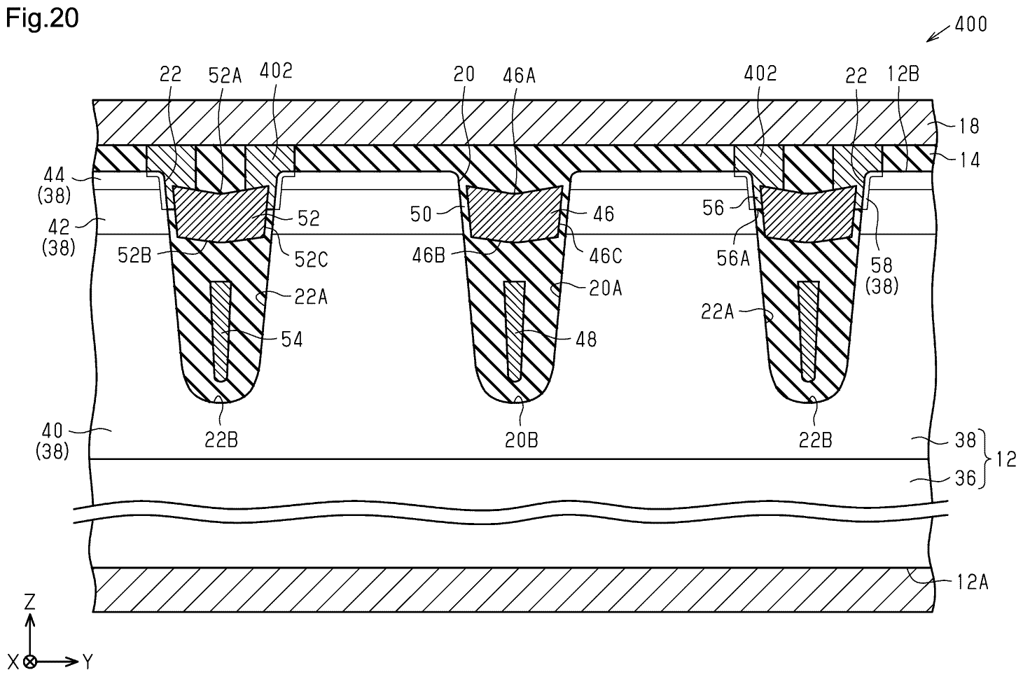

FIG. 20 is a schematic cross-sectional view of the semiconductor device 400 in accordance with the second modified example. In FIG. 20, the same reference characters are given to those elements that are the same as the corresponding elements of the semiconductor device 10. Elements that are the same as the corresponding components of the semiconductor device 10 will not be described in detail.

In the example of FIG. 20, the upper surface 52A of each embedded electrode 52 is partially covered by the corresponding source contact plug 402, and the source contact plug 402 has a smaller width than the corresponding source trench 22. The central part of the upper surface 52A of the embedded electrode 52 is covered by the insulation layer 14, and the remaining part of the upper surface 52A is covered by the corresponding source contact plug 402. This case also allows the source contact plug 402 to electrically connect the source interconnection 18 to the semiconductor layer 12. In the same manner as the source contact plugs 26, each source contact plug 402 contacts the corresponding embedded electrode 52 and contacts the semiconductor layer 12 via the side wall 22A of the corresponding source trench 22. Thus, in the same manner as the first embodiment, in the semiconductor device 400 of the second modified example, the position where the source contact plug 402 contacts the semiconductor layer 12 is aligned with the side wall 22A of the source trench 22. This reduces variations in the characteristics of the semiconductor device 400 (e.g., gate threshold voltage, on resistance, etc.) that would be caused by displacement of the source contact plugs 402. In one example, the second modified example may be applied when the source trench 22 has a relatively large width.

### Other Modified Examples

In each embodiment, the gate electrode 46 and the first field plate electrode 48 are arranged in each gate trench 20. The first field plate electrode 48, however, does not necessarily have to be arranged in the gate trench 20.

The conductivity type of each region in the semiconductor layer 12 may be inverted. That is, the p-type region may be an n-type region, and the n-type region may be a p-type region.

One or more of the various examples described in this specification may be combined as long as there is no technical contradiction.

In this specification, “at least one of A and B” should be understood to mean “only A, only B, or both A and B.”

In this specification, the term “connect” may refer to a state in which two or elements are directly connected or indirectly connected. That is, two or more elements may be connected with or without another element arranged therebetween. In this specification, the terms “connect” and “couple” are interchangeable.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is arranged above the second layer without contacting the second layer in another embodiment. Thus, the word “on” will also allow for a structure in which another layer is arranged between the first layer and the second layer.

The terms used in this specification to indicate directions such as vertical, horizontal, upward, downward, up, down, forward, rearward, side, left, right, front, and back will be attributed to specific directions of the described and illustrated device. In this disclosure, a variety of alternative directions may be available for any given direction. Thus, directional terms should not be construed narrowly.

For example, the Z-axis direction as referred to in this specification does not necessarily have to be the vertical direction and does not necessarily have to fully coincide with the vertical direction. For example, the X-axis direction may be the vertical direction.

Alternatively, the Y-axis direction may be the vertical direction.

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### [Clause 1]

A semiconductor device, including:
a semiconductor layer (12) including a first surface (12A) and a second surface (12B) opposite to the first surface (12A);
a source trench (22) formed in the semiconductor layer (12) and including a side wall (22A) that is continuous with the second surface (12B);
an insulation layer (14) formed on the second surface (12B) of the semiconductor layer (12);
an embedded electrode (52) arranged in the source trench (22) and insulated from the side wall (22A) of the source trench (22) by the insulation layer (14);
a source interconnection (18) formed on the insulation layer (14); and
a source contact plug (26) electrically connecting the source interconnection (18) to the semiconductor layer (12),
where the source contact plug (26) contacts the embedded electrode (52), and the source contact plug (26) contacts the semiconductor layer (12) via a part of the side wall (22A) of the source trench (22).

### [Clause 2]

The semiconductor device according to clause 1, where the semiconductor layer (12) includes a contact region (58) of a first conductivity type formed adjacent to the source contact plug (26), and the contact region (58) extends along the part of the side wall (22A) of the source trench (22).

### [Clause 3]

The semiconductor device according to clause 2, where the embedded electrode (52) includes an upper surface (52A) covered by the source contact plug (26) and a side surface (52C) facing the side wall (22A) of the source trench (22).

### [Clause 4]

The semiconductor device according to clause 3, where the source contact plug (26) includes a lower extension (56) embedded between the side wall (22A) of the source trench (22) and the side surface (52C) of the embedded electrode (52).

### [Clause 5]

The semiconductor device according to clause 4, where
the embedded electrode (52) further includes a bottom surface (52B) opposite to the upper surface (52A), and
the lower extension (56) includes a lower end surface (56A) located between the upper surface (52A) and the bottom surface (52B) of the embedded electrode (52) in a depth direction orthogonal to the second surface (12B).

### [Clause 6]

The semiconductor device according to clause 5, where the lower end surface (56A) is located closer to the bottom surface (52B) of the embedded electrode (52) than to the upper surface (52A) in the depth direction.

### [Clause 7]

The semiconductor device according to clause 5 or 6, where the semiconductor layer (12) includes a drift region (40) of a second conductivity type, a body region (42) of a first conductivity type formed on the drift region (40), and a source region (44) of a second conductivity type formed on the body region (42), the source trench (22) extending through the source region (44) and the body region (42).

### [Clause 8]

The semiconductor device according to clause 7, where the contact region (58) is adjacent to the source region (44) and the body region (42), the contact region (58) having a first conductivity type impurity concentration that is higher than that of the body region (42).

### [Clause 9]

The semiconductor device according to clause 7 or 8, where the lower end surface (56A) is located downward from a boundary of the body region (42) and the drift region (40) in the depth direction.

### [Clause 10]

The semiconductor device according to any one of clauses 4 to 9, where the source contact plug (26) includes a main portion (26a) arranged inside the source trench (22) in plan view and an overhanging portion (26b) arranged outside the source trench (22) in plan view, the lower extension (56) being included in the main portion (26a).

### [Clause 11]

The semiconductor device according to any one of clauses 2 to 10, where the contact region (58) further extends along a part of the second surface (12B) of the semiconductor layer (12).

### [Clause 12]

The semiconductor device according to any one of clauses 1 to 9, where the source contact plug (26) includes an overhanging portion (26b) contacting the second surface (12B) of the semiconductor layer (12).

### [Clause 13]

The semiconductor device according to clause 12, where the overhanging portion (26b) is arranged outside the source trench (22) in plan view.

### [Clause 14]

The semiconductor device according to any one of clauses 1 to 13, further including:
a gate trench (20) formed in the semiconductor layer (12); and
a gate electrode (46) arranged in the gate trench (20),
where the source trench (22) extends in a first direction parallel to the gate trench (20) in plan view.

### [Clause 15]

The semiconductor device according to clause 14, further including a first field plate electrode (48) arranged below the gate electrode (46) in the gate trench (20), where the first field plate electrode (48) is electrically connected to the source interconnection (18).

### [Clause 16]

The semiconductor device according to clause 14 or 15, where
the source trench (22) is one of multiple source trenches (22) formed in the semiconductor layer (12), and the gate trench (20) is one of multiple gate trenches (20) formed in the semiconductor layer (12), and
the gate trenches (20) and the source trenches (22) are arranged alternately in a second direction that is orthogonal to the first direction in plan view.

### [Clause 17]

The semiconductor device according to any one of clauses 1 to 16, further including a second field plate electrode (54) arranged below the embedded electrode (52) in the source trench (22), where the second field plate electrode (54) is electrically connected to the source interconnection (18).

### [Clause 18]

The semiconductor device according to clause 1, where the embedded electrode (52) includes an upper surface (52A) partially covered by the source contact plug (402) and a side surface (52C) facing the side wall (22A) of the source trench (22).

### [Clause 19]

The semiconductor device according to clause 18, where the source contact plug (402) has a smaller width than the source trench (22).

### [Clause 20]

The semiconductor device according to any one of clauses 1 to 19, further including a drain electrode (60) formed on the first surface (12A) of the semiconductor layer (12).

### [Clause 21]

A method for manufacturing a semiconductor device, the method including:
forming a semiconductor layer (12) including a first surface (12A) and a second surface (12B) opposite to the first surface (12A);
forming a source trench (22) including a side wall (22A) continuous with the second surface (12B) in the semiconductor layer (12);
forming an insulation layer (14) and an embedded electrode (52);
forming a source contact plug (26); and
forming a source interconnection (18) on the insulation layer (14), where
the insulation layer (14) is formed on the second surface (12B) of the semiconductor layer (12), and the embedded electrode (52) is arranged in the source trench (22) and insulated from the side wall (22A) of the source trench (22) by the insulation layer (14), and
the source contact plug (26) contacts the embedded electrode (52) and contacts the semiconductor layer (12) via a part of the side wall (22A) of the source trench (22).

### [Clause 22]

The method according to clause 21, where the forming the source contact plug (26) includes forming a source contact opening (78) in the insulation layer (14), and forming the source contact opening (78) includes exposing a part of a side wall (22A) of the source trench (22).

### [Clause 23]

The method according to clause 22, further including forming a contact region (58) by implanting ions from a portion exposed from a side wall (22B) of the source trench (22).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor layer including a first surface and a second surface opposite to the first surface;
a source trench formed in the semiconductor layer and including a side wall that is continuous with the second surface;
an insulation layer formed on the second surface of the semiconductor layer;
an embedded electrode arranged in the source trench and insulated from the side wall of the source trench by the insulation layer;
a source interconnection formed on the insulation layer; and
a source contact plug electrically connecting the source interconnection to the semiconductor layer,
wherein the source contact plug contacts the embedded electrode, and the source contact plug contacts the semiconductor layer via a part of the side wall of the source trench.

2. The semiconductor device according to claim 1, wherein the semiconductor layer includes a contact region of a first conductivity type formed adjacent to the source contact plug, and the contact region extends along the part of the side wall of the source trench.

3. The semiconductor device according to claim 2, wherein the embedded electrode includes an upper surface covered by the source contact plug and a side surface facing the side wall of the source trench.

4. The semiconductor device according to claim 3, wherein the source contact plug includes a lower extension embedded between the side wall of the source trench and the side surface of the embedded electrode.

5. The semiconductor device according to claim 4, wherein
the embedded electrode further includes a bottom surface opposite to the upper surface, and
the lower extension includes a lower end surface located between the upper surface and the bottom surface of the embedded electrode in a depth direction orthogonal to the second surface.

6. The semiconductor device according to claim 5, wherein the lower end surface is located closer to the bottom surface of the embedded electrode than to the upper surface in the depth direction.

7. The semiconductor device according to claim 5, wherein the semiconductor layer includes a drift region of a second conductivity type, a body region of a first conductivity type formed on the drift region, and a source region of a second conductivity type formed on the body region, the source trench extending through the source region and the body region.

8. The semiconductor device according to claim 7, wherein the contact region is adjacent to the source region and the body region, the contact region having a first conductivity type impurity concentration that is higher than that of the body region.

9. The semiconductor device according to claim 7, wherein the lower end surface is located downward from a boundary of the body region and the drift region in the depth direction.

10. The semiconductor device according to claim 4, wherein the source contact plug includes a main portion arranged inside the source trench in plan view and an overhanging portion arranged outside the source trench in plan view, the lower extension being included in the main portion.

11. The semiconductor device according to claim 2, wherein the contact region further extends along a part of the second surface of the semiconductor layer.

12. The semiconductor device according to claim 1, wherein the source contact plug includes an overhanging portion contacting the second surface of the semiconductor layer.

13. The semiconductor device according to claim 12, wherein the overhanging portion is arranged outside the source trench in plan view.

14. The semiconductor device according to claim 1, further comprising:
a gate trench formed in the semiconductor layer; and
a gate electrode arranged in the gate trench,
wherein the source trench extends in a first direction parallel to the gate trench in plan view.

15. The semiconductor device according to claim 14, further comprising a first field plate electrode arranged below the gate electrode in the gate trench, wherein the first field plate electrode is electrically connected to the source interconnection.

16. The semiconductor device according to claim 14, wherein the source trench is one of multiple source trenches formed in the semiconductor layer, and the gate trench is one of multiple gate trenches formed in the semiconductor layer, and the gate trenches and the source trenches are arranged alternately in a second direction that is orthogonal to the first direction in plan view.

17. The semiconductor device according to claim 1, further comprising a second field plate electrode arranged below the embedded electrode in the source trench, wherein the second field plate electrode is electrically connected to the source interconnection.

18. The semiconductor device according to claim 1, wherein the embedded electrode includes an upper surface partially covered by the source contact plug and a side surface facing the side wall of the source trench.

19. The semiconductor device according to claim 18, wherein the source contact plug has a smaller width than the source trench.

20. The semiconductor device according to claim 1, further comprising a drain electrode formed on the first surface of the semiconductor layer.
